(19) United States
(12) Patent Application Publication
(10) Pub. No.: US 2024/0387568 A1
(43) Pub. Date: Nov. 21, 2024

(54) IMAGE SENSORS HAVING IMPROVED OPTICAL CHARACTERISTICS USING ENHANCED ELECTRICAL CONNECTION OF SPACED-APART FLOATING DIFFUSION REGIONS

(71) Applicant: Samsung Electronics Co., Ltd., Suwon-si (KR)

(72) Inventors: Gwideok Ryan Lee, Suwon-si (KR); Gyunha Park, Suwon-si (KR); Jongeun Park, Suwon-si (KR)

(21) Appl. No.: 18/502,903

(22) Filed: Nov. 6, 2023

(30) Foreign Application Priority Data
May 17, 2023 (KR) 10-2023-0063999

(51) Int. Cl. H01L 27/146

(52) U.S. Cl. CPC H01L 27/14603; H01L 27/14612; H01L 27/14636; H01L 27/14643

(57) ABSTRACT

An image sensor includes a substrate having a plurality of photodiodes therein, a plurality of transmission transistors having respective current carrying terminals electrically coupled to corresponding ones of the plurality of photodiodes, and a plurality of floating diffusion regions electrically coupled to current carrying terminals of corresponding ones of the plurality of transmission transistors. A connection wire is also provided, which is configured to electrically interconnect at least four of the plurality of floating diffusion regions together. The connection wire includes: (i) a central connection segment having first and second ends, (ii) a first connection segment having a first end electrically connected to the first end of the central connection segment and a second end electrically connected to a first of the plurality of floating diffusion regions, and (iii) a second connection segment having a first end electrically connected to the second end of the central connection segment and a second end electrically connected to a second of the plurality of floating diffusion regions. The first and central connection segments may be linear segments, and the first end of the first connection segment may intersect with the first end of the central connection segment at an obtuse angle when viewed from a plan layout perspective.

### REFERENCE TO PRIORITY APPLICATION

This application claims priority to Korean Patent Application No. 10-2023-0063999, filed May 17, 2023, the disclosure of which is hereby incorporated herein by reference.

### BACKGROUND

The present disclosure relates to integrated circuit devices and, more particularly, to integrated image sensors.

A CMOS image sensor is a solid-state imaging device that uses complementary metal-oxide semiconductor (CMOS) devices. Compared to CCD image sensors with high-voltage analog circuit, CMOS image sensors have advantages of low manufacturing cost and low power consumption due to a small size of the device, so that they are mainly installed in home appliances in addition to portable devices such as smartphones and digital cameras.

A pixel array configuring the CMOS image sensor includes a photodiode within each pixel (or sub-pixel). As will be understood by those skilled in the art, the photodiode may generate an electrical signal that varies according to an amount of incident light, and the CMOS image sensor may synthesize an image by processing the electrical signal. Recently, according to demands for high-resolution images, a pixel configuring the CMOS image sensor is required to be further down-sized. As the demand for down-sizing increases, incident light may not be properly/sufficiently sensed (i.e., detected), or noise may occur due to interference between elements having increased integration. Nonetheless, despite the down-sizing of the CMOS image sensor, demands for higher image quality improvement and additional functions are increasing.

### SUMMARY

The present disclosure attempts to provide an image sensor having more improved optical characteristics.

An image sensor includes a substrate, a plurality of photodiodes located in the substrate, transmission transistors connected to the plurality of photodiodes, respectively, a plurality of floating diffusion regions connected to at least one photodiode through the transmission transistors, and a connection wire configured to interconnect at least four of the floating diffusion regions. The four floating diffusion regions are located at corresponding vertices of a rectangular shape, respectively. In addition, the connection wire may include a central connection portion located in a central portion of the rectangular shape, and a plurality of bridge portions configured to connect between the central connection portion and each vertex of the rectangular shape. In some embodiments, a first angle between two bridge portions connected to a first side end portion of the central connection portion among the plurality of bridge portions is an obtuse angle. Also, an angle between the bridge portion and a short side of the rectangular shape is smaller than an angle between the short side and a diagonal line of the rectangular shape.

According to a further embodiment, an image sensor is provided that includes a substrate, a plurality of photodiodes located in the substrate, transmission transistors connected to corresponding ones of the plurality of photodiodes, a plurality of floating diffusion regions connected to at least two photodiodes through the transmission transistors, and a connection wire configured to interconnect at least four of the floating diffusion regions. Advantageously, the four floating diffusion regions may be located at corresponding vertices of a quadrangular shape, and a length of the connection wire may be smaller than a sum of lengths of two diagonal lines of the quadrangular shape, so that the optical characteristics of the image sensor may be improved by reducing the length of the connection wire of the image sensor.

An image sensor according to another embodiment includes a substrate, a plurality of photodiodes located in the substrate, transmission transistors connected to corresponding ones of the plurality of photodiodes, a plurality of floating diffusion regions connected to at least four photodiodes through the transmission transistor, and a connection wire configured to interconnect at least four floating diffusion regions. In addition, a plurality of color filters are provided, which are located on the plurality of photodiodes, and a plurality of microlenses are provided, which are located on the plurality of color filters. Advantageously, the four floating diffusion regions may be located at respective vertices of a rectangular shape, and the connection wire may include a central connection portion that is located in a central portion of the rectangular shape and extends parallel to a long side of the rectangular shape. A plurality of bridge portions are also provided, which are configured to connect between the central connection portion and each vertex of the rectangular shape. In some of these embodiments, the angles between the central connection portion and the plurality of bridge portions may be greater than 90 degrees and smaller than 135 degrees.

An image sensor according to a further embodiment of the invention may include: a substrate having a plurality of photodiodes therein, a plurality of transmission transistors having respective current carrying terminals electrically coupled to corresponding ones of the plurality of photodiodes, and a plurality of floating diffusion regions electrically coupled to current carrying terminals of corresponding ones of the plurality of transmission transistors. A connection wire may also be provided, which electrically interconnects at least four of the plurality of floating diffusion regions together and is configured to improve image sensor optical characteristics. In some embodiments, the connection wire may include: (i) a central connection segment having first and second ends, (ii) a first connection segment having a first end electrically connected to the first end of the central connection segment and a second end electrically connected to a first of the plurality of floating diffusion regions, and (iii) a second connection segment having a first end electrically connected to the second end of the central connection segment and a second end electrically connected to a second of the plurality of floating diffusion regions. And, in some of these embodiments, the first and central connection segments may be patterned as linear segments, with the first end of the first connection segment intersecting with the first end of the central connection segment at an obtuse angle when viewed from a plan layout perspective. The four of the plurality of floating diffusion regions may also be located at respective vertices of a rectangle when viewed from a plan layout perspective; and the central connection segment may extend parallel to a line connecting the first and second floating diffusion regions, when viewed from the plan layout perspective.

According to still further embodiments of the invention, an image sensor may include: (i) a substrate having a plurality of photodiodes therein, (ii) a plurality of transmission transistors having respective current carrying terminals electrically coupled to corresponding ones of the plurality of photodiodes, (iii) a plurality of floating diffusion regions electrically coupled to current carrying terminals of corresponding ones of the plurality of transmission transistors, and (iv) a connection wire. In some embodiments, the plurality of floating diffusion regions include first, second, third and fourth floating diffusion regions located at respective first, second, third and fourth vertices of a rectangle when viewed from a plan layout perspective. In addition, the connection wire, which is configured to electrically interconnect the first, second, third and fourth floating diffusion regions together, may consist of multiple connection segments having a total length when summed together that is less than a sum of: (i) a length of a first diagonal line of the rectangle extending between the first and fourth floating diffusion regions, and (ii) a length of a second diagonal line of the rectangle extending between the second and third floating diffusion regions. In some instances, the connection wire may consist of five connection segments, and four of these five connection segments may be configured to terminate above respective ones of the first, second, third and fourth floating diffusion regions, relative to a surface of the substrate containing the plurality of floating diffusion regions therein.

### BRIEF DESCRIPTION OF THE DRAWINGS

FIG. 1 is a block diagram schematically illustrating an image sensor according to an embodiment.

FIG. 2 is a top plan view showing a layout of a pixel array of an image sensor according to an embodiment.

FIG. 3 is a circuit diagram showing a pixel of an image sensor according to an embodiment.

FIG. 4 and FIG. 5 are top plan views that schematically show a layout of a pixel group of an image sensor according to an embodiment.

FIG. 6 is a top plan view schematically showing a connection wire of an image sensor according to an embodiment.

FIG. 7 is a cross-sectional view taken along line A-A′ of FIG. 5.

FIG. 8 is a cross-sectional view taken along line B-B′ of FIG. 5.

FIG. 9 to FIG. 11 are top plan views that schematically illustrate alternative layouts of pixel groups of an image sensor according to some embodiments.

FIG. 12 is an enlarged view of region P1 of FIG. 11.

FIG. 13 to FIG. 17 are a top plan views schematically showing alternative layouts of pixel groups of an image sensor according to some embodiments.

FIG. 18 and FIG. 19 are top plan views schematically showing a layout of color filters within an image sensor according to an embodiment.

FIG. 20 and FIG. 21 are top plan views schematically showing a layout of microlenses within of an image sensor according to an embodiment.

FIG. 22 to FIG. 24 are drawings illustrating various examples of electronic devices to which image sensors according to example embodiments can be applied.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present invention, parts or portions that are irrelevant to the description are omitted, and identical or similar constituent elements throughout the specification are denoted by the same reference numerals. Furthermore, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements. Also, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

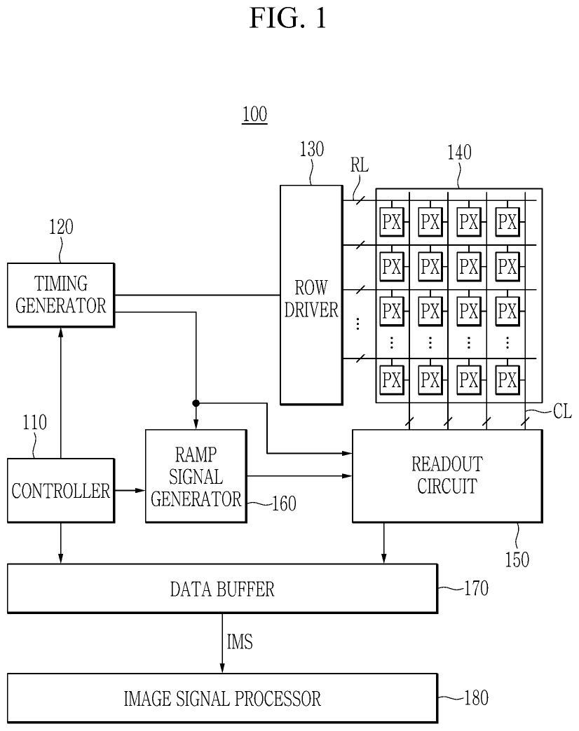

An image sensor according to an embodiment will be described with reference to FIG. 1, which is a block diagram schematically illustrating an image sensor according to an embodiment. Referring to FIG. 1, an image sensor 100 according to an embodiment may include a pixel array 140 and a logic circuit controlling the pixel array 140. The logic circuit may include, for example, a controller 110, a timing generator 120, a row driver 130, a readout circuit 150, a ramp signal generator 160, and a data buffer 170.

In addition, the image sensor 100 may further include an image signal processor 180, and in some embodiments, the image signal processor 180 may be provided external to the image sensor 100. The image sensor 100 may generate an image signal by converting light received from the outside into an electrical signal(s). The image signal(s) may be provided to the image signal processor 180.

In some embodiments, the image sensor 100 may be mounted on an electronic device having an image or optical sensing function. For example, the image sensor 100 may be mounted on electronic devices, such as a camera, a smartphone, a wearable device, an Internet of things (IoT) device, a home appliance, a tablet personal computer (PC), a navigation device, a drone, an advanced driver assistance systems (ADAS), and the like. In addition, the image sensor 100 may be mounted on an electronic device provided as a component in a vehicle, furniture, a manufacturing facility, a door, various measurement devices, or the like.

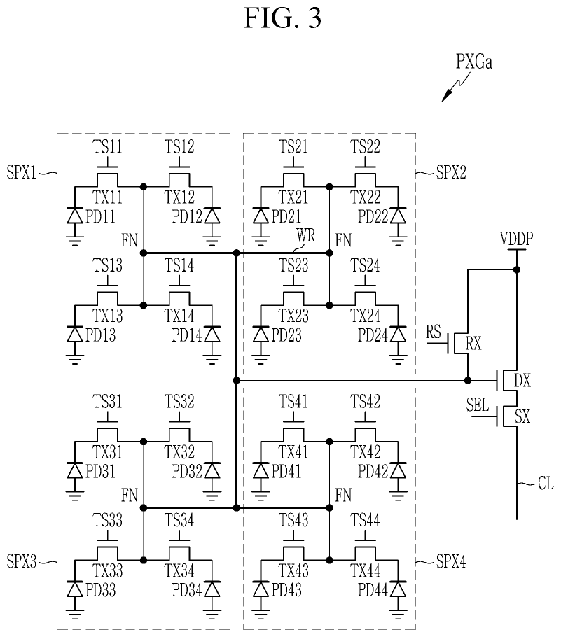

The pixel array 140 may include a plurality of pixels PX, and a plurality of row lines RL and a plurality of column lines CL respectively connected to the plurality of pixels PX. In an embodiment, each pixel PX may include at least one photodiode. The photodiode may sense incident light, and may convert the incident light into an electrical signal(s) (i.e., a plurality of analog pixel signals) according to an amount of the light. In some embodiments, each photodiode may be a photodiode (refer to PD in FIG. 3), a pinned diode, and the like. In addition, each photodiode may be a single-photon avalanche diode (SPAD) applied to a 3D sensor pixel. As will be understood by those skilled in the art, the level of the analog pixel signal(s) output from the photodiode may be proportional to the amount of charge output from the photodiode. That is, the level of the analog pixel signal outputted from the photodiode may be determined according to an amount of light received into the pixel array 140.

The plurality of row lines RL may be connected to the plurality of pixels PX. For example, a control signal outputted from the row driver 130 to the row line RL may be transmitted to a gate of a transistor of the plurality of pixels PX connected to the corresponding row line RL. The column line CL may be disposed to cross the row line RL, and may be connected to the plurality of pixels PX. The plurality of pixel signals outputted from the plurality of pixels PX may be transmitted to the readout circuit 150 through the plurality of column lines CL.

In an embodiment, the plurality of pixels PX may be disposed along a plurality of columns and a plurality of rows, and one analog pixel signal may be outputted for each pixel PX. However, the embodiment is not limited thereto, and numerous variations are possible. For example, the plurality of pixels PX may be grouped in the form of a plurality of columns and a plurality of rows to configure one unit pixel group. One unit pixel may include a plurality of pixels PX arranged in the form of two rows and two columns, and one unit pixel may output one analog pixel signal.

The controller 110 may control an operation timing of each of the constituent elements 120, 130, 150, 160, and 170 described above by using control signals. For example, in some embodiments, the controller 110 may receive a mode signal indicating an imaging mode from an application processor, and may overall control the image sensor 100 based on the received mode signal. For example, the application processor may determine the imaging mode of the image sensor 100 according to various scenarios such as illumination of the imaging environment, a user's resolution setting, a sensed or learned state, and may provide the determined result to the controller 110 as a mode signal.

In addition, the controller 110 may control the plurality of pixels PX of the pixel array 140 to output pixel signals according to the imaging mode, the pixel array 140 may output a pixel signal for each of the plurality of pixels PX or a pixel signal for some of the plurality of pixels PX, and the readout circuit 150 may sample and process pixel signals transmitted from the pixel array 140.

The timing generator 120 may generate a signal serving as a reference for operation timing of components of the image sensor 100. The timing generator 120 may control the timing of the row driver 130, the readout circuit 150, and the ramp signal generator 160, by providing control signals for controlling the timing of the row driver 130, the readout circuit 150, and the ramp signal generator 160. In addition, the row driver 130 may generate a control signal for driving the pixel array 140 in response to the control signal from the timing generator 120, and may provide control signals to the plurality of pixels PX of the pixel array 140 through the plurality of row lines RL.

In an embodiment, the row driver 130 may control the pixel PX to sense incident light in a row line unit. The row line unit may include at least one row line RL. For example, the row driver 130 may generate a transmission signal for controlling a transmission transistor, a reset control signal for controlling a reset transistor, and a selection control signal for controlling a selection transistor to provide the generated signals to the pixel array 140.

The readout circuit 150 may convert the pixel signal (or electrical signal) from the pixel PX connected to the row line RL selected from the plurality of pixels PX in response to the control signal from the timing generator 120 into a pixel value representing the amount of light. In particular, the readout circuit 150 may convert a pixel signal outputted through the corresponding column line CL into a pixel value. For example, the readout circuit 150 may convert a pixel signal into a pixel value by comparing a ramp signal and a pixel signal. The pixel value may be image data having a plurality of bits. Specifically, the readout circuit 150 may include a selector, a plurality of comparator, and a plurality of counter circuits.

The ramp signal generator 160 may generate a reference signal to transmit it to the readout circuit 150. The ramp signal generator 160 may include a current source, a resistor, and a capacitor. The ramp signal generator 160 adjusts a ramp voltage, which is a voltage applied to a ramp resistor, by adjusting a current amount of a variable current source or a resistance value of a variable resistor, so that the ramp signal generator 140 may generate a plurality of ramp signals that fall or rise with a slope determined according to the current amount of the variable current source or the resistance value of the variable resistor.

The data buffer 170 may store pixel values of the plurality of pixels PX connected to the selected column line CL transmitted from the readout circuit 150, and may output the stored pixel values in response to an enable signal from the controller 110. In addition, the image signal processor 180 may perform image signal processing on the image signal received from the data buffer 170. For example, the image signal processor 180 may receive a plurality of image signals from the data buffer 170, and may synthesize the received image signals to generate an image(s).

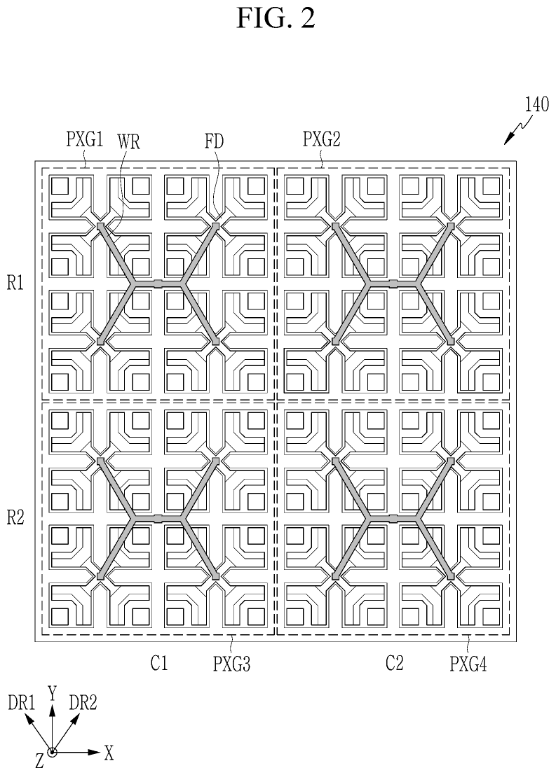

Hereinafter, a pixel array of an image sensor according to an embodiment will be described with reference to FIG. 2, which is a top plan “layout” view showing a pixel array of an image sensor according to an embodiment. Referring to FIG. 2, the pixel array 140 may include a plurality of pixel groups, for example, first to fourth pixel groups PXG1 to PXG4. The plurality of pixel groups may be arranged in a plurality of rows and columns. FIG. 2 shows the first to fourth pixel groups PXG1 to PXG4 arranged in first and second rows R1 and R2 and first and second columns C1 and C2, but it is merely for convenience of description, and the pixel array 140 may include a greater number of pixel groups, and the number of pixel groups may be determined according to the resolution of the pixel array 140.

The plurality of row lines (RL of FIG. 1) extends in a first direction (X-direction), and pixel groups disposed in the same row may be connected to the same row line. For example, the first and second pixel groups PXG1 and PXG2 disposed in a first row R1 may be connected in common to one row line, and third and fourth pixel groups PXG3 and PXG4 disposed in a second row R2 may be connected in common to another row line.

A plurality of column lines (CL in FIG. 1) may, for example, extend in a second direction (Y-axis direction), and pixels disposed in the same column may be connected to the same column line. For example, the first and third pixel groups PXG1 and PXG3 disposed in a first column C1 may be connected in common to one column line, and the second and fourth pixel groups PXG2 and PXG4 disposed in a second column C2 may be connected in common to another column line. A pixel signal may be read through a column line in a row unit from a plurality of pixels.

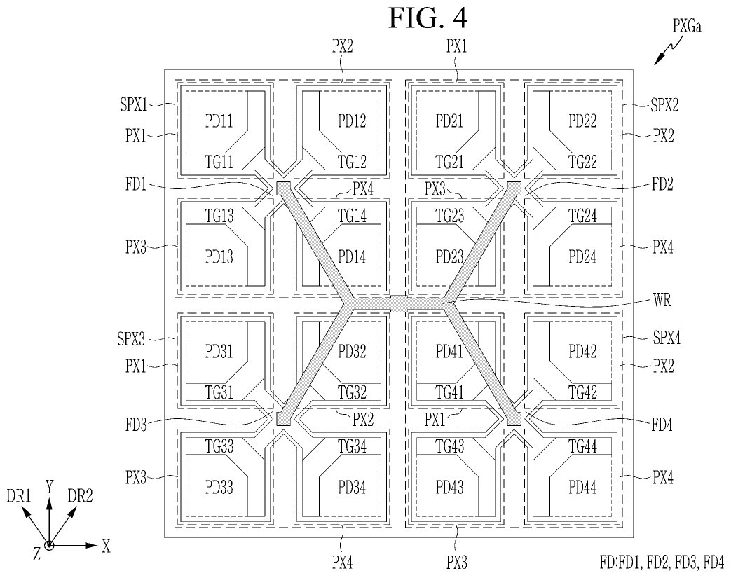

Each of the first to fourth pixel groups PXG1 to PXG4 may include a plurality of floating diffusion regions FD in which charge, which is generated in response to incident light, is at least temporarily stored. The plurality of floating diffusion regions FD in a pixel may be electrically connected through a connection wire WR extending in the first direction (X-direction), a first diagonal direction DR1 crossing the first direction (X-direction) and the second direction (Y-direction), and a second diagonal direction DR2 crossing the first diagonal direction DR1. The first to fourth pixel groups PXG1 to PXG4 may have substantially the same pixel structure, and the pixel structure may be as described in detail below in FIG. 4 and thereafter.

Hereinafter, a circuit structure of one pixel group of an image sensor according to an embodiment will be described with reference to FIG. 3, which is a circuit diagram showing a pixel of an image sensor according to an embodiment. The pixel group PXGa of FIG. 3 may be applied as representative of the first to fourth pixel groups PXG1 to PXG4 of the pixel array 140 of FIG. 2.

Referring to FIG. 3, each of the plurality of pixel groups PXGa of an image sensor according to an embodiment may include first to fourth sub-pixel groups SPX1 to SPX4, a reset transistor RX, a driving transistor DX, and a selection transistor SX. The reset transistor RX, the driving transistor DX, and the selection transistor SX may configure an output circuit of the pixel group PXGa.

A first sub-pixel group SPX1 may include first to fourth photodiodes PD11 to PD14, and first to fourth transmission transistors TX11 to TX14. The first to fourth photodiodes PD11 to PD14 may respectively generate photo-charges (hereinafter, referred to as charges) corresponding to the amount of light received.

The first to fourth photodiodes PD11 to PD14 may be connected to the first to fourth transmission transistors TX11 to TX14, respectively. The first to fourth transmission transistors TX11 to TX14 of the first sub-pixel group SPX1 may be turned-on in response to active levels (for example, logic high) of transmission signals TS11 to TS14, respectively.

A second sub-pixel group SPX2 may include first to fourth photodiodes PD21 to PD24, and first to fourth transmission transistors TX21 to TX24 connected to the first to fourth photodiodes PD21 to PD24, respectively. The first to fourth transmission transistors TX21 to TX24 of the second sub-pixel group SPX2 may be turned-on in response to active levels (for example, logic high) of transmission signals TS21 to TS24, respectively.

A third sub-pixel group SPX3 may include first to fourth photodiodes PD31 to PD34, and first to fourth transmission transistors TX31 to TX34 connected to the first to fourth photodiodes PD31 to PD34, respectively. First to fourth transmission transistors TX31 to TX34 of the third sub-pixel group SPX3 may be turned-on in response to active levels (for example, logic high) of transmission signals TS31 to TS34, respectively.

A fourth sub-pixel group SPX4 may include first to fourth photodiodes PD41 to PD44, and first to fourth transmission transistors TX41 to TX44 connected to the first to fourth photodiodes PD41 to PD44, respectively. The first to fourth transmission transistors TX41 to TX44 of the fourth sub-pixel group SPX4 may be turned-on in response to active levels (for example, logic high) of transmission signals TS41 to TS44, respectively.

A plurality of transmission signals TS11 to TS14, TS21 to TS24, TS31 to TS34, and TS41 to TS44 may have the active levels, at a same or different time points, depending on a read mode. For example, in a first read mode, the plurality of transmission signals TS11 to TS14, TS21 to TS24, TS31 to TS34, and TS41 to TS44 are different signals, and may have the active level at different time points. In a second read mode (for example, charge summation mode), plurality of transmission signals TS11 to TS14, TS21 to TS24, TS31 to TS3, and TS41 to TS44 are the same signals, and may have the active level at the same time point. In a third read mode, the transmission signals TS11 to TS14 of the first sub-pixel group SPX1 may be the same signal, the transmission signals TS21 to TS24 of the second sub-pixel group SPX2 may be the same signal, the transmission signals TS31 to TS34 of the third sub-pixel group SPX3 may be the same signal, and the transmission signals TS41 to TS44 of the fourth sub-pixel group SPX4 may be the same signal, but is not limited thereto.

The first to fourth transmission transistors TX11 to TX14, TX21 to TX24, TX31 to TX34, and TX41 to TX44 provided in the first to the first to fourth sub-pixel groups SPX1 to SPX4, respectively, may be turned-on to transmit charges generated at corresponding photodiodes to a floating diffusion node FN. The first to fourth sub-pixel groups SPX1 to SPX4 may include first to fourth floating diffusion regions (refer to FD1 to FD4 in FIG. 4), respectively. As the first to fourth floating diffusion regions are electrically connected to each other through the connection wire WR, a single floating diffusion node FN may be formed in each pixel group PXGa.

Accordingly, the capacitance of the capacitor formed at the floating diffusion node FN may be greater than the capacitance of each of the first to fourth floating diffusion regions (refer to FD1 to FD4 in FIG. 4). For example, the capacitance of the capacitor formed at the floating diffusion node FN may be four (4) times the capacitance of each of the first to fourth floating diffusion regions (refer to FD1 to FD4 in FIG. 4), but is not limited thereto.

A reset signal RS is applied to a gate of the reset transistor RX, a power supply voltage VDDP is supplied to a first end of the reset transistor RX, and a second end of the reset transistor RX may be connected to the floating diffusion node FN. The reset transistor RX may be turned-on in response to the active level of the reset signal RS, such that the floating diffusion node FN may be reset to the power supply voltage VDDP.

The driving transistor DX may output a pixel signal according to the voltage of the floating diffusion node FN. A gate of the driving transistor DX is connected to the floating diffusion node FN, the power supply voltage VDDP is supplied to a first end of the driving transistor DX, and a second end of the driving transistor DX is connected to a first end of the selection transistor SX. The driving transistor DX may constitute a source follower circuit, and may output a voltage having a level corresponding to the charge accumulated in the floating diffusion node FN as a pixel signal.

When the selection transistor SX is turned-on by a selection signal SEL, a pixel signal from the driving transistor DX may be transferred to the readout circuit 150 through the column line CL. The selection signal SEL is applied to a gate of the selection transistor SX, and a second end of the selection transistor SX is connected to the column line CL.

Meanwhile, FIG. 3 shows that the pixel group PXGa incudes one reset transistor RX, one driving transistor DX, and one selection transistor SX, but is not limited thereto. The pixel group PXGa provided in the pixel array 140 may include two reset transistor, two driving transistor, and two selection transistors, respectively. Alternatively, the pixel group PXGa may include three or more reset transistors, driving transistors, and selection transistors, respectively.

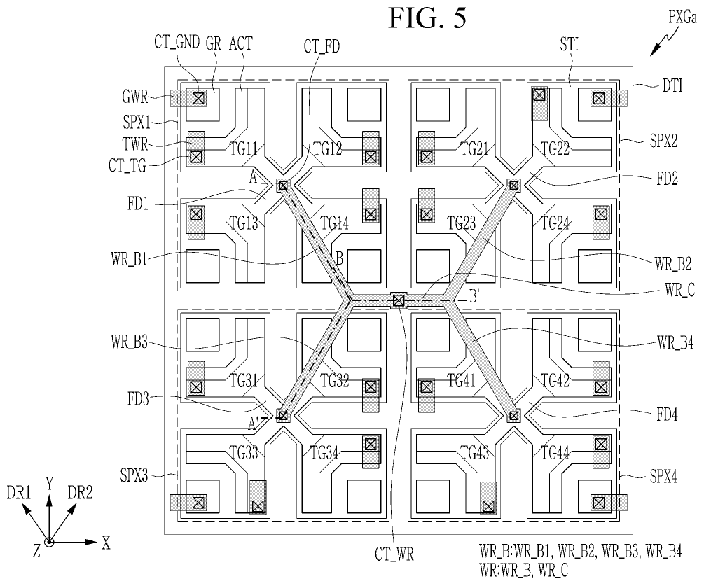

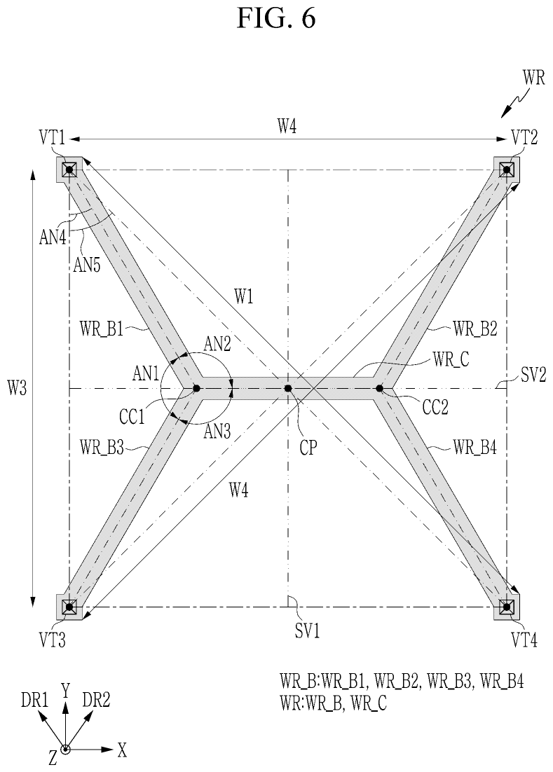

Hereinafter, a planar arrangement structure of one pixel group of an image sensor according to an embodiment will be described with reference to FIGS. 4 to 6. In particular, FIG. 4 and FIG. 5 are top plan view schematically showing a pixel group of an image sensor according to an embodiment. FIG. 6 is a top plan view schematically showing a connection wire of an image sensor according to an embodiment.

FIG. 4 shows photodiodes PD11 to PD14, PD21 to PD24, PD31 to PD34, and PD41 to PD44, transfer gates TG11 to TG14, TG21 to TG24, TG31 to TG34, and TG41 to TG44, floating diffusion regions FD1 to FD4, and the connection wire WR, without showing an active region ACT, a ground region GR, a transfer gate wire TWR, and a ground wire GWR. FIG. 5 shows transfer gates TG11 to TG14, TG21 to TG24, TG31 to TG34, and TG41 to TG44, floating diffusion regions FD1 to FD4, the connection wire WR, the active region ACT, the ground region GR, the transfer gate wire TWR, and the ground wire GWR, without showing the photodiodes PD11 to PD14, PD21 to PD24, PD31 to PD34, and PD41 to PD44.

The pixel group PXGa of FIG. 4 and FIG. 5 may correspond to each of the first to fourth pixel groups PXG1 to PXG4 of the pixel array 140 of FIG. 2. Thus, referring to FIG. 4 and FIG. 5, the pixel group PXGa may include the first to fourth sub-pixel groups SPX1 to SPX4, and the connection wire WR connecting between the first to fourth sub-pixel groups SPX1 to SPX4. Each of the first to fourth sub-pixel groups SPX1 to SPX4 may have substantially the same pixel structure, but is not limited thereto.

The first to fourth sub-pixel groups SPX1 to SPX4 may include the first to fourth pixels PX1 to PX4 arranged along the plurality of columns and the plurality of rows, respectively. The first sub-pixel group SPX1 may include the first to fourth photodiodes PD11 to PD14, the first to fourth transfer gates TG11 to TG14, and a first floating diffusion region FD1.

First to fourth pixels PX1 to PX4 each of the first sub-pixel group SPX1 may include one photodiode and one transfer gate. For example, the first pixel PX1 of the first sub-pixel group SPX1 may include the first photodiode PD11 and the first transfer gate TG11. The second pixel PX2 may include the second photodiode PD12 and the second transfer gate TG12. The third pixel PX3 may include the third photodiode PD13 and the third transfer gate TG13. The fourth pixel PX4 may include a fourth photodiode PD14 and the fourth transfer gate TG14.

The first to fourth transfer gates TG11 to TG14 may be gates of the first to fourth transmission transistors (refer to TX11 to TX14 in FIG. 3), respectively. Each of the first to fourth transmission transistors (refer to TX11 to TX14 in FIG. 3) may be connected to the first to fourth photodiodes PD11 to PD14. As described above, the first to fourth transmission transistors TX11 to TX14 may transmit the charge generated by the first to fourth photodiodes PD11 to PD14 to the first floating diffusion region FD1, respectively. Therefore, the received charges may be stored in the first floating diffusion region FD1.

The first to fourth photodiodes PD11 to PD14 may be 2-dimensionally arranged in a plan view. The first to fourth photodiodes PD11 to PD14 may be arranged along the plurality of columns and the plurality of rows. For example, the first to fourth photodiodes PD11 to PD14 may be arranged in the form of two rows and two columns. Centers of the first to fourth photodiodes PD11 to PD14 may be located at respective vertices of quadrangular shape. For example, the centers of the first to fourth photodiodes PD11 to PD14 may be located at respective vertices of a rectangular shape (e.g., square, rectangle).

The first floating diffusion region FD1 may be disposed at a center of the first sub-pixel group SPX1. The first to fourth transfer gates TG11 to TG14 may be disposed to surround the first floating diffusion region FD1. The first floating diffusion region FD1 may have a generally X-shape in a plan view, and the first to fourth transfer gates TG11 to TG14 may be located at an end portion of the first floating diffusion region FD1, respectively. The first to fourth transfer gates TG11 to TG14 may be circularly symmetrical with respect to the first floating diffusion region FD1.

The first floating diffusion region FD1 may be connected to at least one photodiode through transmission transistor (refer to TX11 to TX14 in FIG. 3). For example, the first floating diffusion region FD1 may be connected to the first to fourth photodiodes PD11 to PD14 arranged along the plurality of columns and the plurality of rows through the first to fourth transmission transistors, as shown by TX11 to TX14 in FIG. 3. However, it is not limited thereto, and the number of photodiodes to which the first floating diffusion region FD1 is connected may vary. For example, the first floating diffusion region FD1 may be connected to two photodiodes through two transmission transistors. Alternatively, the first floating diffusion region FD1 may be connected to eight photodiode through eight transmission transistors.

The second sub-pixel group SPX2 may include the first to fourth photodiodes PD21 to PD24, the first to fourth transfer gates TG21 to TG24, and a second floating diffusion region FD2. The third sub-pixel group SPX3 may include the first to fourth photodiodes PD31 to PD34, the first to fourth transfer gates TG31 to TG34, and a third floating diffusion region FD3. The fourth sub-pixel group SPX4 may include the first to fourth photodiodes PD41 to PD44, the first to fourth transfer gates TG41 to TG44, and a fourth floating diffusion region FD4. Pixel structures of the second to fourth sub-pixel groups SPX2 to SPX4 are the same as the first sub-pixel group SPX1, and redundant description is not included here.

In addition, through the second floating diffusion region FD2 of the second sub-pixel group SPX2 may be connected to at least one photodiode through transmission transistor. For example, the second floating diffusion region FD2 may be connected to the first to fourth photodiodes PD21 to PD24 through the first to fourth transmission transistors (refer to TX21 to TX24 in FIG. 3) of the second sub-pixel group SPX2. The third floating diffusion region FD3 of the third sub-pixel group SPX3 may be connected to at least one photodiode through transmission transistor. For example, the third floating diffusion region FD3 may be connected to the first to fourth photodiodes PD31 to PD34 through the first to fourth transmission transistors (refer to TX31 to TX34 in FIG. 3) of the third sub-pixel group SPX3.

The fourth floating diffusion region FD4 of the fourth sub-pixel group SPX4 may be connected to at least one photodiode through transmission transistor. For example, the fourth floating diffusion region FD4 may be connected to the first to fourth photodiodes PD41 to PD44 through the first to fourth transmission transistors (refer to TX41 to TX44 in FIG. 3) of the fourth sub-pixel group SPX4.

In summary, each of the first to fourth floating diffusion regions FD1 to FD4 may be connected to at least one photodiode through transmission transistors (refer to TX11 to TX14, TX21 to TX24, TX31 to TX34, and TX41 to TX44 in FIG. 3). Each of the transmission transistors (refer to TX11 to TX14, TX21 to TX24, TX31 to TX34, and TX41 to TX44 in FIG. 3) may be turned-on by signals applied to transfer gates TG11 to TG14, TG21 to TG24, TG31 to TG34, and TG41 to TG44, and transfer the charge generated by each photodiode to the first to fourth floating diffusion regions FD1 to FD4.

In addition, referring further to FIG. 6, the first to fourth floating diffusion regions FD1 to FD4 may be located at respective vertices of quadrangular shape. For example, each of the first to fourth floating diffusion regions FD1 to FD4 may be located corresponding to first to fourth vertices VT1 to VT4 of the rectangular shape. However, it is not limited thereto, each of the first to fourth floating diffusion regions FD1 to FD4 may be located at each vertex of a convex quadrangle such as a trapezoid, a parallelogram, or a rhombus.

The connection wire WR may be located in a pixel area in which the pixel group PXGa is formed in a plan view. For example, in FIG. 2, the connection wire WR provided in a first pixel group PXG1 is formed in the pixel region of the first pixel group PXG1, and may not extend to another pixel group, for example, second to fourth pixel group PXG2 to PXG4.

The connection wire WR may be connected to the first to fourth floating diffusion regions FD1 to FD4 through a floating diffusion contact CT_FD. The first to fourth floating diffusion regions FD1 to FD4 may be electrically connected to each other through the connection wire WR, to form a single floating diffusion node (refer to FN in FIG. 3). Accordingly, the first to fourth sub-pixel groups SPX1 to SPX4 may share the first to fourth floating diffusion regions FD1 to FD4, and an available area of the pixel group PXGa may be increased.

FIG. 4 and FIG. 5 show that the connection wire WR is connected to four floating diffusion regions FD, but is not limited thereto. For example, the connection wire WR may be connected to one floating diffusion region FD. Alternatively, the connection wire WR may be connected to two or three floating diffusion regions FD. In addition, the connection wire WR may be connected to five or more floating diffusion regions FD.

Referring further to FIG. 6, the first to fourth floating diffusion regions FD1 to FD4 may be located at the first to fourth vertices VT1 to VT4 of the quadrangular shape, respectively. A central portion of each of the first to fourth floating diffusion regions FD1 to FD4 may be connected to the connection wire WR, including five (5) segments WR_C, WR_B1, WR_B2, WR_B3 and WR_B4 that collectively form a generally H-shaped connection wire WR that is referred to herein (and in the claims) as a “diverging” H-shaped connection wire WR, as shown by FIG. 6, with first, second and third angles AN1, AN2 and AN3 all being obtuse angles. At this time, the central portion of each of the first to fourth floating diffusion regions FD1 to FD4 may be located at the first to fourth vertices VT1 to VT4 of the quadrangular shape. That is, floating diffusion contacts CT_FD configured to connect between the first to fourth floating diffusion regions FD1 to FD4 and the connection wire WR may be located at the first to fourth vertices VT1 to VT4 of the quadrangular shape.

At this time, a Fermat-Torricelli (FT) point may be located in the quadrangular shape. Here, the FT point refers to a point at which line segments connecting to respective vertices of the quadrangular shape have a minimum length. When electrically connecting the plurality of floating diffusion regions FD, the FT point may be a point that may minimize a parasitic capacitance generated by the connection wire WR. The FT point may be a node separated into each floating diffusion region FD a first side end portion and/or a second side end portion of a central connection portion WR_C.

In an embodiment, as shown in FIG. 6, the first to fourth floating diffusion regions FD1 to FD4 may be located at the first to fourth vertices VT1 to VT4 of the rectangular shape, respectively. In this case, the connection wire WR may include first and second nodes CC1 and CC2 for minimizing a length to connect the first to fourth floating diffusion regions FD1 to FD4. Here, each of the first and second nodes CC1 and CC2 may be the above-mentioned FT point. Accordingly, the first to fourth floating diffusion regions FD1 to FD4 may be connected in a minimum length by the connection wire WR connected through the first and second nodes CC1 and CC2.

However, it is not limited thereto, and the first and second nodes CC1 and CC2 each of the connection wire WR may not be precisely located at the FT point. For example, the first and second nodes CC1 and CC2 of the connection wire WR may be located adjacent to the FT point. Even in this case, the length of the connection wire WR may be relatively reduced. A description of this will be given later.

Accordingly, the length of the connection wire WR may be smaller than a sum of lengths of two diagonal lines of the quadrangular shape. That is, the length of the connection wire WR may be shorter than when the respective vertices of the quadrangular shape are connected in an X shape. For example, when the first to fourth floating diffusion regions FD1 to FD4 are located at the first to fourth vertices VT1 to VT4 of the rectangular shape, respectively, the length of the connection wire WR may be smaller than a sum of a first distance W1 between the first vertex VT1 and the fourth vertex VT4 of the rectangular shape and a second distance W2 between the second vertex VT2 and the third vertex VT3 of the rectangular shape.

In addition, the length of the connection wire WR may be smaller than a sum of twice a length of a short side of the rectangular shape and a length of a long side of the rectangular shape. That is, the length of the connection wire WR may be shorter than when the respective vertices of the quadrangular shape are connected in a diverging H shape. For example, the length of the connection wire WR may be smaller than a sum of twice a third distance W3 of between the first vertex VT1 and the third vertex VT3 of the rectangular shape and a fourth distance W4 of between the first vertex VT1 and the second vertex VT2 of the rectangular shape. Here, since the first to fourth floating diffusion regions FD1 to FD4 are located at the first to fourth vertices VT1 to VT4 of the rectangular shape, respectively, the third distance W3 between the first vertex VT1 and the third vertex VT3 of the rectangular shape may be substantially the same as a distance between the second vertex VT2 and the fourth vertex VT4 of the rectangular shape. In addition, the fourth distance W4 between the first vertex VT1 and the second vertex VT2 of the rectangular shape may be substantially the same as a distance between the third vertex VT3 and the fourth vertex VT4 of the rectangular shape.

The connection wire WR may include the central connection portion WR_C located at a central portion of the rectangular shape and a plurality of bridge portions WR_B configured to connect between the central connection portion WR_C and the first to fourth vertices VT1 to VT4 of the rectangular shape.

The central connection portion WR_C may be located above a pixel separator DTI. For example, as shown in FIG. 4 and FIG. 5, the central connection portion WR_C may be located above a portion of the pixel separator DTI configured to separate between the first sub-pixel group SPX1 and the third sub-pixel group SPX3 and between the second sub-pixel group SPX2 and the fourth sub-pixel group SPX4.

When the first to fourth floating diffusion regions FD1 to FD4 are located at the first to fourth vertices VT1 to VT4 of the rectangular shape, respectively, the central connection portion WR_C may be extended in the first direction (X-direction). For example, the central connection portion WR_C may extend parallel to the long side of the rectangular shape. Length along the first direction (X-direction) of the central connection portion WR_C may be shorter than the length of the long side of the rectangular shape. The central connection portion WR_C may be symmetrical with respect to a first reference line SV1 extending in the second direction (Y-direction) at the center point CP of the rectangular shape.

However, the direction in which the central connection portion WR_C extends is not limited thereto. For example, when the first to fourth floating diffusion regions FD1 to FD4 are not located at the first to fourth vertices VT1 to VT4 of the rectangular shape, respectively (for example, when the first to fourth floating diffusion regions FD1 to FD4 are located at the first to fourth vertices VT1 to VT4 of asymmetric trapezoid shape, respectively), the central connection portion WR_C may not extend in the first direction (X-direction). The direction in which the center connection portion WR_C extends may be determined according to the positional relationship between the vertices of the quadrangle in which the first to fourth floating diffusion regions FD1 to FD4 are respectively located. Alternatively, the direction in which the central connection portion WR_C extends may be determined by angles that the central connection portion WR_C forms with respect to the plurality of bridge portions WR_B, to be described later, which may be determined according to a design capable of minimizing the length of the connection wire WR.

Therefore, hereinafter, for convenience of description, the following is an exemplary case in which the first to fourth floating diffusion regions FD1 to FD4 according to an embodiment are located at the first to fourth vertices VT1 to VT4 of the rectangular shape, respectively.

The plurality of bridge portions WR_B may connect between the central connection portion WR_C and the first to fourth vertices VT1 to VT4 of the rectangular shape. For example, a first bridge portion WR_B1 may connect between the central connection portion WR_C and the first vertex VT1 of the rectangular shape, and a second bridge portion WR_B2 may connect between the central connection portion WR_C and the second vertex VT2 of the rectangular shape. A third bridge portion WR_B3 may connect between the central connection portion WR_C and the third vertex VT3 of the rectangular shape, and a fourth bridge portion WR_B4 may connect between the central connection portion WR_C and the fourth vertex VT4 of the rectangular shape.

Each of the first to fourth bridge portions WR_B1 to WR_B4 may extend in one direction. For example, each of the first and fourth bridge portion WR_B1 and WR_B4 may extend in the first direction (X-direction) and the first diagonal direction DR1 crossing the second direction (Y-direction). The second and third bridge portions WR_B1 and WR_B3 may extend in the second diagonal direction DR2 crossing the first diagonal direction DR1. In addition, each of the first to fourth bridge portions WR_B1 to WR_B4 may have substantially the same shape. For example, each of the first to fourth bridge portions WR_B1 to WR_B4 may have a bar shape having a constant width.

In this case, the first to fourth bridge portions WR_B1 to WR_B4 may be symmetrical. Specifically, the first to fourth bridge portions WR_B1 to WR_B4 may be circularly symmetrical with respect to the center point CP of the rectangular shape. In addition, the first to fourth bridge portions WR_B1 to WR_B4 may be symmetrical with respect to the first reference line SV1 extending in the second direction (Y-direction) at the center point CP of the rectangular shape. For example, the first and third bridge portions WR_B1 and WR_B3 may be symmetrical to the second and fourth bridge portions WR_B2 and WR_B4 with respect to the first reference line SV1. In addition, the first to fourth bridge portions WR_B1 to WR_B4 may be symmetrical with respect to a second reference line SV2 extending in the first direction (X-direction) at the center point CP of the rectangular shape. The first to fourth bridge portions WR_B1 to WR_B4 may be symmetrical with respect to the central connection portion WR_C. For example, each of the first and second bridge portions WR_B1 and WR_B2 may be symmetrical to each of the third and fourth bridge portions WR_B3 and WR_B4 with respect to the second reference line SV2.

Accordingly, angles between the central connection portion WR_C and respective ones in the plurality of bridge portions WR_B may be substantially the same with each other. For example, a second angle AN2 between the central connection portion WR_C and the first bridge portion WR_B1 may be substantially the same as a third angle AN3 between the central connection portion WR_C and the third bridge portion WR_B3.

However, it is not limited thereto, when the first to fourth floating diffusion regions FD1 to FD4 are located at the first to fourth vertices VT1 to VT4 of the quadrangular shape that is not the rectangular shape, respectively, the first to fourth bridge portions WR_B1 to WR_B4 may not be symmetrical with respect to the center point CP of the quadrangular shape.

Some of the plurality of bridge portions WR_B may be connected to a first side end portion of the central connection portion WR_C, and the other thereof may be connected to a second side end portion of the central connection portion WR_C. For example, the first bridge portion WR_B1 and the third bridge portion WR_B3 may be connected to the first side end portion of the central connection portion WR_C. The second bridge portion WR_B2 and the fourth bridge portion WR_B4 may be connected to the second side end portion of the central connection portion WR_C.

An angle between two bridge portions, among the plurality of bridge portions WR_B, connected to the first side end portion of the central connection portion WR_C may be in a predetermined range. For example, a first angle AN1 between the first bridge portion WR_B1 and the third bridge portion WR_B3 may be obtuse angle. The first angle AN1 between the first bridge portion WR_B1 and the third bridge portion WR_B3 may be larger than 90 degrees, and smaller than 180 degrees.

Here, as the first angle AN1 between the first bridge portion WR_B1 and the third bridge portion WR_B3 is larger, a length of the central connection portion WR_C connected to the first bridge portion WR_B1 and the third bridge portion WR_B3 may be increased. In addition, as the first angle AN1 between the first bridge portion WR_B1 and the third bridge portion WR_B3 is smaller, lengths of the first bridge portion WR_B1 and the third bridge portion WR_B3 may be increased. Therefore, when the first angle AN1 between the first bridge portion WR_B1 and the third bridge portion WR_B3 is greater than 90 degrees and smaller than 180 degrees, an entire length of the connection wire WR may be decreased than when the first angle AN1 between the first bridge portion WR_B1 and the third bridge portion WR_B3 is 180 degrees. The first angle AN1 between the first bridge portion WR_B1 and the third bridge portion WR_B3 may be greater than or equal to a preferably 110 degrees, and smaller than or equal to 130 degrees. More preferably, the first angle AN1 between the first bridge portion WR_B1 and the third bridge portion WR_B3 may be 120 degrees. The entire length of the connection wire WR may become a minimum when the first angle AN1 is 120 degrees.

Accordingly, angles between the central connection portion WR_C and the plurality of bridge portions WR_B may be greater than 90 degrees, and smaller than 135 degrees. For example, the second angle AN2 between the central connection portion WR_C and the first bridge portion WR_B1 may be greater than 90 degrees, and smaller than 135 degrees. In addition, the third angle AN3 between the central connection portion WR_C and the third bridge portion WR_B3 may be greater than 90 degrees, and smaller than 135 degrees. Angles between the central connection portion WR_C and the plurality of bridge portions WR_B may be preferably greater than or equal to 115 degrees, and smaller than or equal to 125 degrees. For example, when the first angle AN1 between the first bridge portion WR_B1 and the third bridge portion WR_B3 is 120 degrees, angles between the central connection portion WR_C and the plurality of bridge portions WR_B may be 120 degrees. At this time, the entire length of the connection wire WR may be a minimum.

In addition, an angle between one among the plurality of bridge portions WR_B and the short side of the rectangular shape may be smaller than an angle between the short side of the rectangular shape and the diagonal line of the rectangular shape. For example, a fourth angle AN4 between the first bridge portion WR_B1 and the short side of the rectangular shape may be smaller than a fifth angle AN5 between the short side of the rectangular shape and the diagonal line of the rectangular shape.

An angle between the second bridge portion WR_B2 and the fourth bridge portion WR_B4 may be obtuse angle. An angle between the second bridge portion WR_B2 and the central connection portion WR_C and an angle between the fourth bridge portion WR_B4 and the central connection portion WR_C may be greater than 90 degrees, and smaller than 135 degrees.

Description for the angle between the second bridge portion WR_B2 and the fourth bridge portion WR_B4, the angle between the second bridge portion WR_B2 and the central connection portion WR_C, and the angle between the fourth bridge portion WR_B4 and the central connection portion WR_C is substantially the same as have been described with respect to the first angle AN1 between the first bridge portion WR_B1 and the third bridge portion WR_B3, the second angle AN2 between the first bridge portion WR_B1 and the central connection portion WR_C, and the third angle AN3 between the third bridge portion WR_B3 and the central connection portion WR_C, respectively, and is not redundantly included here again.

Referring back to FIG. 5, the image sensor 100 according to an embodiment may include the transfer gate wire TWR electrically connected to each of transfer gates TG11 to TG14, TG21 to TG24, TG31 to TG34, and TG41 to TG44, and the ground wire GWR electrically connected to the ground region GR. The transfer gate wire TWR may be electrically connected to each of transfer gates TG11 to TG14, TG21 to TG24, TG31 to TG34, and TG41 to TG44 through a transfer gate contact CT_TG. The transfer gate wire TWR may overlap each of transfer gates TG11 to TG14, TG21 to TG24, TG31 to TG34, and TG41 to TG44 in a third direction (Z-direction). The transfer gate wire TWR may be located in the same layer as the connection wire WR. The transfer gate wire TWR may not electrically connected to the connection wire WR. That is, the transfer gate wire TWR may non-overlap the connection wire WR in the third direction (Z-direction).

Among transfer gates TG11 to TG14, TG21 to TG24, TG31 to TG34, and TG41 to TG44, at least one transfer gate may overlap at least a portion of the connection wire WR. For example, the fourth transfer gate TG14 of the first sub-pixel group SPX1 may overlap a portion of the connection wire WR in the third direction (Z-direction). In addition, the third transfer gate TG23 of the second sub-pixel group SPX2, the second transfer gate TG32 of the third sub-pixel group SPX3, and the first transfer gate TG41 of the fourth sub-pixel group SPX4 may overlap a portion of the connection wire WR in the third direction (Z-direction).

The ground wire GWR may be electrically connected through the ground region GR and a ground contact CT_GND. The ground wire GWR may be located in the same layer as the connection wire WR. The ground wire GWR may not electrically connected to the connection wire WR. That is, the ground wire GWR may non-overlap the connection wire WR in the third direction (Z-direction).

The connection wire WR of the image sensor 100 according to an embodiment may connect between the first to fourth floating diffusion regions FD1 to FD4. Therefore, the first to fourth sub-pixel groups SPX1 to SPX4 may share the first to fourth floating diffusion regions FD1 to FD4. In addition, the first to fourth sub-pixel groups SPX1 to SPX4 may share the output circuit. Accordingly, an available area of the pixel group PXGa may be increased. Since the first to fourth floating diffusion regions FD1 to FD4 are shared within the pixel group PXGa, sensing sensitivity of the pixel group PXGa may be increased. Accordingly, resolution and sensing sensitivity of the pixel array 140 may be increased.

In this case, parasitic capacitance between the connection wire WR and peripheral elements may decrease as the length of the connection wire WR decreases. The connection wire WR of the image sensor 100 according to an embodiment includes the central connection portion WR_C and the plurality of bridge portions WR_B, an angle between the central connection portion WR_C and the plurality of bridge portions WR_B and between two bridge portions connected to the first side end portion of the central connection portion WR_C is in a predetermined range, and thereby the length of the connection wire WR may be decreased. Accordingly, parasitic capacitance between the connection wire WR and peripheral elements may be decreased, and optical characteristics of the image sensor 100 may be improved.

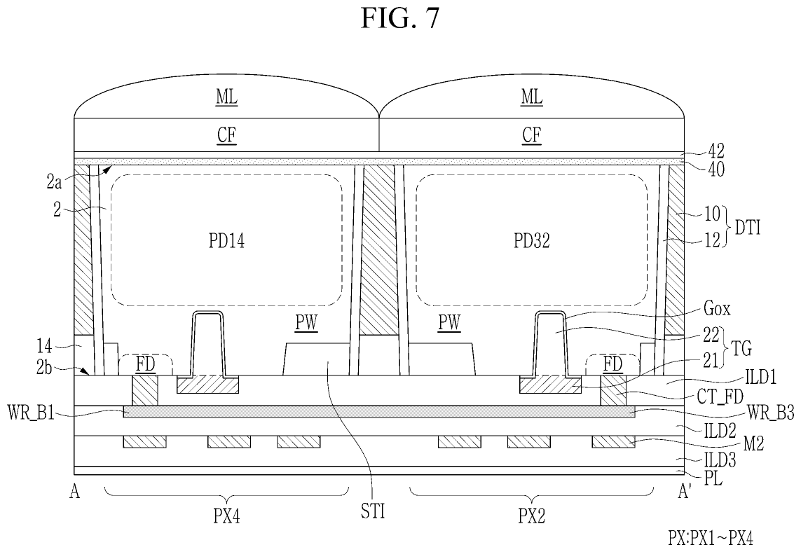

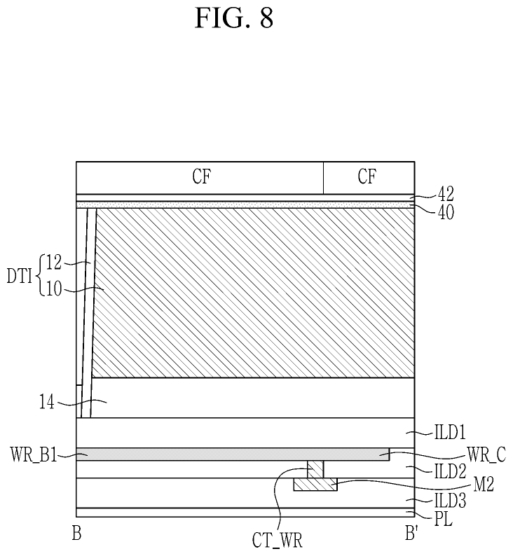

Hereinafter, an image sensor according to an embodiment will be described with reference to FIG. 7 and FIG. 8. FIG. 7 is a cross-sectional view taken along line A-A′ of FIG. 5. FIG. 8 is a cross-sectional view taken along line B-B′ of FIG. 5. Referring to FIG. 7 and FIG. 8, the image sensor 100 according to an embodiment may include a substrate 2, a transfer gate TG located in the substrate 2, a floating diffusion region FD, and photodiodes PD, a color filters CF, and a microlenses ML.

The substrate 2 may be, for example, a bulk silicon or a silicon-on-insulator (SOI). The substrate 310 may be a silicon substrate, or may include other materials, for example, a silicon germanium, an indium antimonide, a lead tellurium compound, an indium arsenic, an indium phosphide, a gallium arsenic, or a gallium antimonide. Alternatively, the substrate 2 may have an epitaxial layer formed on a base substrate. The substrate 2 may be doped with impurities. For example, the substrate 2 may be doped with P-type impurity.

The substrate 2 may include a first surface 2a and a second surface 2b facing each other. The first surface 2a of the substrate 2 may be a light receiving surface on which light is incident. In addition, the first surface 2a may be a front surface of the substrate 2, and the second surface 2b may be a rear surface of the substrate 2. The image sensor 100 according to an embodiment may further include the pixel separator DTI located between adjacent sub-pixel groups SPX and between adjacent pixels PX. The pixel separator DTI may penetrate the substrate 2. For example, the pixel separator DTI extends in the third direction (Z-direction) in a cross-sectional view, and may connect the first surface 2a and the second surface 2b of the substrate 2. However, it is not limited thereto, and in some embodiments, the pixel separator DTI may not penetrate the substrate 2, and may be spaced apart from the second surface 2b of the substrate 2.

The pixel separator DTI may be located between adjacent sub-pixel groups SPX. For example, the pixel separator DTI may separate between the first sub-pixel group SPX1 and the third sub-pixel group SPX3 and between the second sub-pixel group SPX2 and the fourth sub-pixel group SPX4. In addition, the pixel separator DTI may separate between the first sub-pixel group SPX1 and the second sub-pixel group SPX2 and between the third sub-pixel group SPX3 and the fourth sub-pixel group SPX4.

The pixel separator DTI may be located between adjacent pixels PX. For example, the pixel separator DTI may be located each between the first to fourth pixels PX1 to PX4. Each of the first to fourth pixels PX1 to PX4 may be separated by the pixel separator DTI.

The element separation film may extend in a first direction (X direction) and a second direction (Y direction) in a plan view, and may be disposed between the photodiodes PD adjacent to each other. The pixel separator DTI may separate adjacent photodiodes electrically and/or optically. The pixel separator DTI may include a separation conductive pattern 10 spaced apart from the substrate 2. The separation conductive pattern 10 may include a conductive material having a refractive index different from that of the substrate 2. The separation conductive pattern 10 may include, for example, polysilicon or metal doped with impurities. The pixel separator DTI may further include a separation insulation pattern 12 interposed between the separation conductive pattern 10 and the substrate 2. The separation insulation pattern 12 may include an insulating material having a refractive index different from that of the substrate 2. For example, the separation insulation pattern 12 may include silicon oxide.

The image sensor 100 according to an embodiment may further include a capping insulation pattern 14 and an isolation layer STI. The capping insulation pattern 14 may be disposed under the separation conductive pattern 10. The capping insulation pattern 14 may include, for example, at least one of silicon oxide, silicon oxynitride, and silicon nitride.

The isolation layer STI may be located on a side surface of the capping insulation pattern 14. The isolation layer STI may be formed by a shallow trench Isolation (STI) method. The isolation layer STI may be formed in a single layer or multilayer structure of at least one of silicon oxide, silicon nitride and silicon oxynitride layer.

A transfer gate TG may be mounted in the substrate 2. The transfer gate TG may be a vertical type. Specifically, the transfer gate TG may include a first transfer gate portion 21 disposed on the second surface 2b of the substrate 2 and a second transfer gate portion 22 protruding into the substrate 2. Alternatively, as another example, the transfer gate TG may be a planar type including only the first transfer gate portion 21 without the second transfer gate portion 22. A gate insulation layer Gox may be interposed between the transfer gate TG and the substrate 2. The gate insulation layer Gox may include a single layer or multilayer of at least one of silicon oxide, metal oxide silicon nitride, silicon oxynitride layer.

The floating diffusion region FD may be located in the substrate 2. The floating diffusion region FD may be formed to have a predetermined depth from the second surface 2b of the substrate 2. The floating diffusion region FD may be doped with impurities doped to the substrate 2. For example, the floating diffusion region FD may be doped with N-type impurity (e.g., phosphorus or arsenic).

The photodiodes PD for receiving light may be located in the substrate 310. Light incident from the outside may be converted into electrical signals by the photodiodes PD. The photodiode PD may be disposed to correspond to each pixel PX. For example, the fourth photodiode PD14 may be located to correspond to the fourth pixel PX4, and the second photodiode PD32 may be located to correspond to the second pixel PX2. The photodiodes PD may be doped with impurities other than impurities doped to the substrate 2. For example, the photodiodes PD may be doped with N-type impurity.

The image sensor 100 according to an embodiment may further include a well region PW located between the photodiode PD and the second surface 2b. For example, P-type impurity doped in the substrate 2 may be doped in the well region PW. A concentration of impurities doped in the well region PW may be greater than or equal to a concentration of impurities doped in the substrate 2. The photodiodes PD may be doped with impurities. For example, the photodiodes PD may be doped with N-type impurity (e.g., phosphorus or arsenic). A region doped with N-type impurity of the photodiodes PD may form a PN junction with the surrounding substrate 2 and/or the P-type impurity region of the well region PW to form the photodiodes PD, and when the light is incident, electron-hole pairs may be generated by the PN junction.

The image sensor 100 according to an embodiment may further include first to third interlayer insulation layers ILD1, ILD2, and ILD3, a passivation layer PL, a fixed charge layer 40 and an anti-reflection layer 42. The first to third interlayer insulation layers ILD1, ILD2, and ILD3 and the passivation layer PL may be sequentially stacked on the second surface 2b of the substrate 2. The first to third interlayer insulation layers ILD1, ILD2, and ILD3 may have a single layer or multilayer structure of at least one of, for example, silicon oxide, silicon nitride, silicon oxynitride, porous insulator, respectively. The passivation layer PL may include, for example, silicon nitride.

The connection wire WR may be located between the first interlayer insulation layer ILD1 and the second interlayer insulation layer ILD2. The connection wire WR may be connected to the floating diffusion region FD by the floating diffusion contact CT_FD penetrating the first interlayer insulation layer ILD1.

Although not shown in FIG. 7 and FIG. 8, first wires may be further located between the first interlayer insulation layer ILD1 and the second interlayer insulation layer ILD2.

Some of the first wires may be transfer gate wires TWR. That is, the transfer gate wire TWR may be located in the same layer as the connection wire WR. The transfer gate wire TWR may be connected to the transfer gate TG by the transfer gate contact CT_TG penetrating the first interlayer insulation layer ILD1.

Another part of the first wires may be a ground wire GWR. That is, the ground wire GWR may be located in the same layer as the connection wire WR. The ground wire GWR may be connected to the ground region GR by the ground contact CT_GND penetrating the first interlayer insulation layer ILD1. A ground voltage or a negative bias voltage may be applied to the ground region GR by the ground contact CT_GND.

The first wires may non-overlap the connection wire WR in the third direction (Z-direction). For example, the transfer gate wire TWR may non-overlap the connection wire WR in the third direction (Z-direction). In addition, the ground wire GWR may non-overlap the connection wire WR in the third direction (Z-direction).

Second wirings M2 may be located between the second interlayer insulation layer ILD2 and the third interlayer insulation layer ILD3. The connection wire WR may be connected to some of the second wirings M2 by a connection wire contact CT_WR penetrating the second interlayer insulation layer ILD2. In addition, some of the first wires may be connected to some of the second wirings M2 by via penetrating the second interlayer insulation layer ILD2.

The fixed charge layer 40 may be located above the first surface 2a of the substrate 2. The fixed charge layer 40 may be in contact with the first surface 2a. The fixed charge layer 40 may be made of metal oxide or metal fluoride including at least one metal selected from a group including hafnium (Hf), zirconium (Zr), aluminum (Al), tantalum (Ta), titanium (Ti), yttrium and lanthanoids. Hole accumulation may occur around the fixed charge layer 40. As a result, generation of dark current and white spots may be effectively reduced. Preferably, the fixed charge layer 40 may be at least one of an aluminum oxide layer and a hafnium oxide layer. The anti-reflection layer 42 may be located on the fixed charge layer 40. The anti-reflection layer 42 may include, for example, silicon nitride.

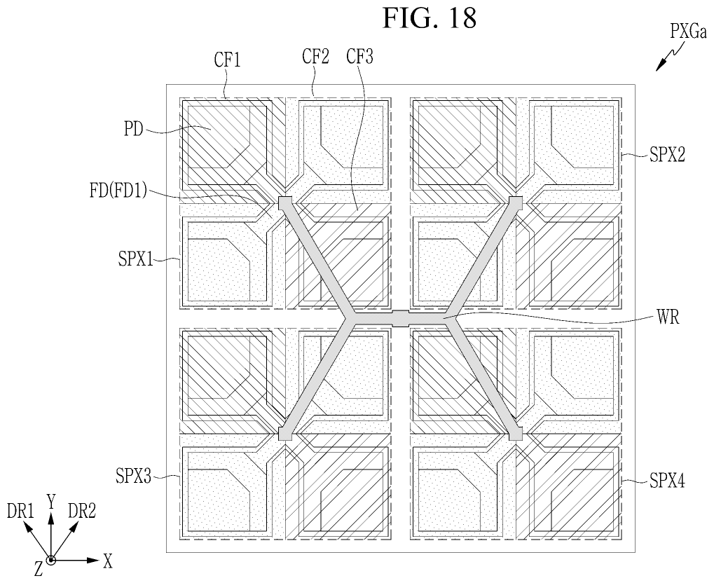

The color filters CF may be located above the anti-reflection layer 42. Each of the color filters CF may be disposed to correspond to each of the photodiodes PD. The microlenses ML condensing light incident from the outside may be disposed on each color filter CF. The color filters CF and the microlenses ML will be described later with reference to FIG. 18 to FIG. 21.

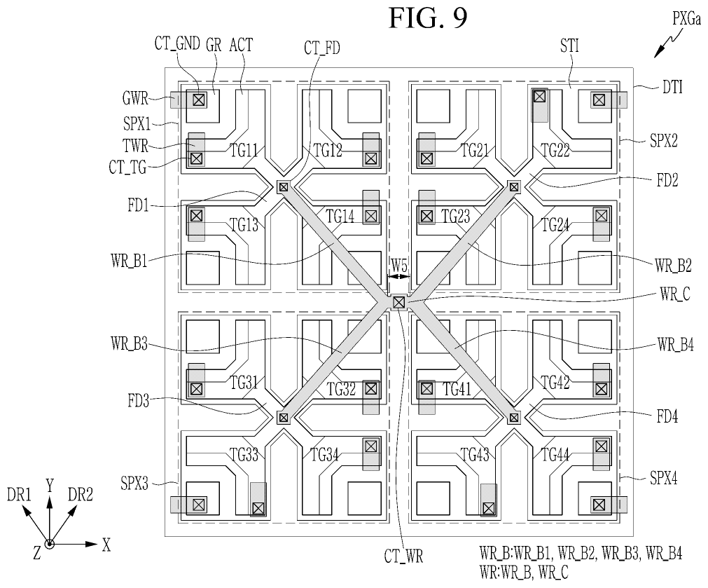

Hereinafter, other embodiments of the image sensor will be described with reference to FIG. 9 to FIG. 15. FIG. 9 is a top plan view schematically showing a pixel group of an image sensor according to some embodiments. An image sensor according to an embodiment shown in FIG. 9 has substantially same parts as an image sensor according to an embodiment shown in FIG. 1 to FIG. 8, and thus the following description is more focused on differences while omitting redundant explanations

In addition, the same reference numerals are used for components that are the same as those of the previous embodiment. The present embodiment differs from the above embodiments in a width of the central connection portion WR_C, which will be described below.

Referring to FIG. 9, in the same way as in the above embodiment, the pixel group PXGa may be applied to the first to fourth pixel groups PXG1 to PXG4 of the pixel array 140 of FIG. 2. The pixel group PXGa of the image sensor 100 according to some embodiments may include the first to fourth sub-pixel groups SPX1 to SPX4, and the connection wire WR connecting the first to fourth sub-pixel groups SPX1 to SPX4. The connection wire WR may include the central connection portion WR_C located at the central portion of the rectangular shape and the plurality of bridge portions WR_B configured to connect between the central connection portion WR_C and the first to fourth vertices VT1 to VT4 of the rectangular shape. The central connection portion WR_C of the above embodiment may be located above a portion of the pixel separator DTI configured to separate between the first sub-pixel group SPX1 and the third sub-pixel group SPX3 and between the second sub-pixel group SPX2 and the fourth sub-pixel group SPX4.

Referring to FIG. 9, the central connection portion WR_C of the present embodiment may not be located above a portion of the pixel separator DTI configured to separate between the first sub-pixel group SPX1 and the third sub-pixel group SPX3. In addition, it may not be located above a portion of the pixel separator DTI configured to separate between the second sub-pixel group SPX2 and the fourth sub-pixel group SPX4. That is, the central connection portion WR_C may no overlap each of the first to fourth sub-pixel groups SPX1 to SPX4 in the second direction (Y-direction). In addition, it may not overlap each of the first to fourth sub-pixel groups SPX1 to SPX4 in the second direction (Y-direction). Accordingly, a fifth width W5 along the first direction (X-direction) of the central connection portion WR_C may be smaller than a width along the first direction (X-direction) of the pixel separator DTI extending in the second direction (Y-direction).

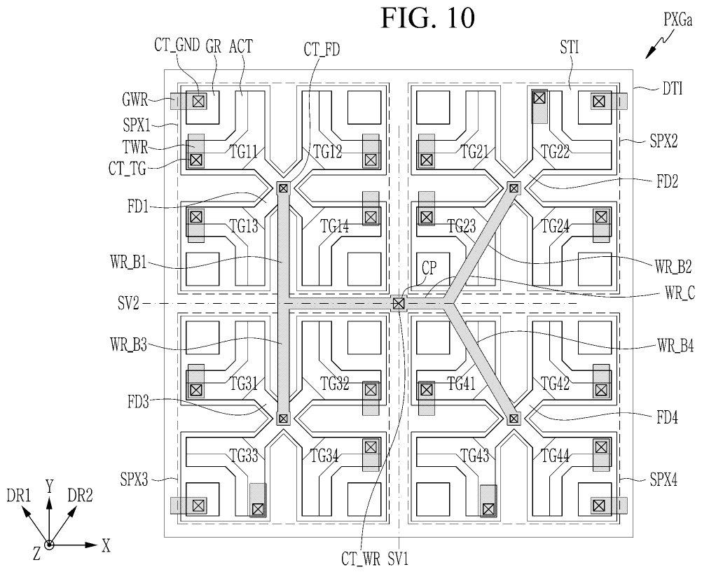

FIG. 10 is a top plan view schematically showing a pixel group of an image sensor according to some embodiments. An image sensor according to an embodiment shown in FIG. 10 has substantially same parts as an image sensor according to an embodiment shown in FIG. 1 to FIG. 8, and thus the following description is more focused on differences while omitting redundant explanations

In addition, same reference numerals are used for same elements as in the previous embodiment. The present embodiment differs from the above embodiments in a shape of the connection wire WR, which will be described below.

Referring to FIG. 10, in the same way as in the above embodiment, the pixel group PXGa may be applied to the first to fourth pixel groups PXG1 to PXG4 of the pixel array 140 of FIG. 2. The pixel group PXGa of the image sensor 100 according to some embodiments may include the first to fourth sub-pixel groups SPX1 to SPX4, and the connection wire WR configured to connect the first to fourth sub-pixel groups SPX1 to SPX4. The connection wire WR may include the central connection portion WR_C located at the central portion of the rectangular shape and the plurality of bridge portions WR_B configured to connect between the central connection portion WR_C and the first to fourth vertices VT1 to VT4 of the rectangular shape.

The connection wire WR of the above embodiment may be circularly symmetrical with respect to the center point CP of the rectangular shape. Specifically, the central connection portion WR_C may be symmetrical with respect to the first reference line SV1 extending in the second direction (Y-direction) at the center point CP of the rectangular shape. In addition, the first to fourth bridge portions WR_B1 to WR_B4 may be symmetrical. Specifically, the first to fourth bridge portions WR_B1 to WR_B4 may be circularly symmetrical with respect to the center point CP of the rectangular shape.

Referring to FIG. 10, the connection wire WR of the present embodiment may not be circularly symmetrical with respect to the center point CP of the rectangular shape. In more detail, the central connection portion WR_C may further extend to one side from the center point CP of the rectangular shape. In addition, the first to fourth bridge portions WR_B1 to WR_B4 may not be symmetrical with respect to the first reference line SV1 extending in the second direction (Y-direction) at the center point CP of the rectangular shape. For example, the first bridge portion WR_B1 may not be symmetrical to the second bridge portion WR_B2 with respect to the first reference line SV1.

Accordingly, angles between the central connection portion WR_C and respective ones in the plurality of bridge portions WR_B may be different from each other. For example, angle between the central connection portion WR_C and the first bridge portion WR_B1 may be different from an angle between the central connection portion WR_C and the second bridge portion WR_B2. In addition, angle between the central connection portion WR_C and the third bridge portion WR_B3 may be different from an angle between the central connection portion WR_C and the fourth bridge portion WR_B4.

At this time, the first to fourth bridge portions WR_B1 to WR_B4 may be symmetrical with respect to the second reference line SV2 extending in the first direction (X-direction) at the center point CP of the rectangular shape. The first to fourth bridge portions WR_B1 to WR_B4 may be symmetrical with respect to the central connection portion WR_C. For example, each of the first and second bridge portions WR_B1 and WR_B2 may be symmetrical to each of the third and fourth bridge portions WR_B3 and WR_B4 with respect to the second reference line SV2.

However, FIG. 10 shows that the plurality of bridge portions WR_B is symmetrical with respect to the second reference line SV2, but is not limited thereto. For example, the plurality of bridge portions WR_B may be symmetrical with respect to the first reference line SV1, but not symmetrical with respect to the second reference line SV2. As another example, the plurality of bridge portions WR_B may not have symmetry at all.

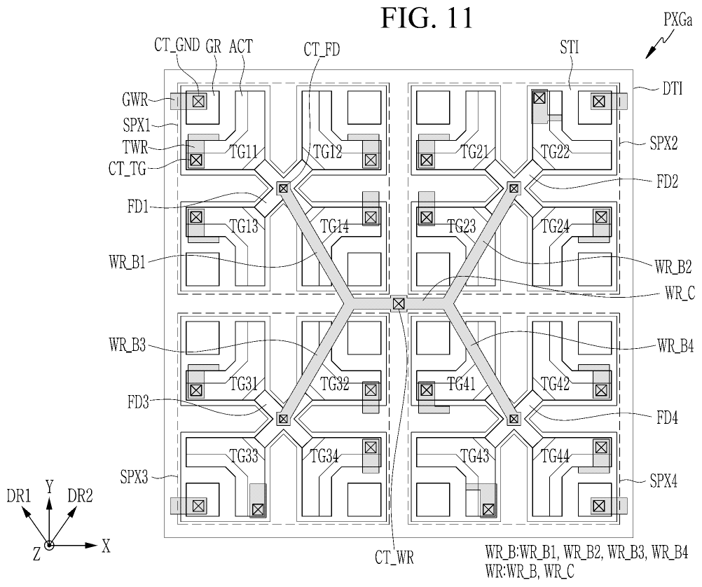

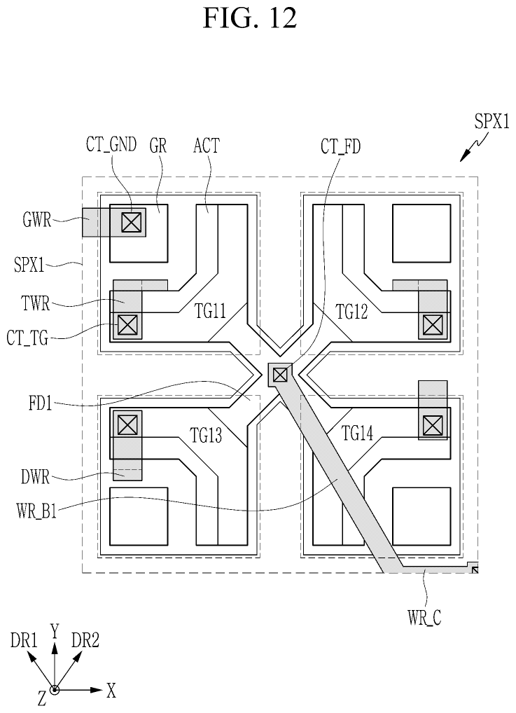

FIG. 11 is a top plan view schematically showing a pixel group of an image sensor according to some embodiments. FIG. 12 is an enlarged view of a first sub-pixel group of FIG. 11. An image sensor according to an embodiment shown in FIG. 11 and FIG. 12 has substantially same parts as an image sensor according to an embodiment shown in FIG. 1 to FIG. 8, and thus the following description is more focused on differences while omitting redundant explanations. In addition, same reference numerals are used for same elements as in the previous embodiment. The present embodiment differs from the above embodiments in a shape of the transfer gate wire TWR, which will be described below.

Referring to FIG. 11 and FIG. 12, in the same way as in the above embodiment, the pixel group PXGa of the image sensor 100 according to some embodiments may include the connection wire WR configured to connect the first to fourth sub-pixel groups SPX1 to SPX4, and the first to fourth sub-pixel groups SPX1 to SPX4, the transfer gate wire TWR electrically connected to each of transfer gates TG11 to TG14, TG21 to TG24, TG31 to TG34, and TG41 to TG44, and the ground wire GWR electrically connected to the ground region GR. The transfer gate wire TWR of the image sensor 100 according to the present embodiment may further include a dummy wiring portion DWR.

As described above, among transfer gates TG11 to TG14, TG21 to TG24, TG31 to TG34, and TG41 to TG44, at least one transfer gate may overlap at least a portion of the connection wire WR. For example, the fourth transfer gate TG14 of the first sub-pixel group SPX1 may overlap a portion of the connection wire WR in the third direction (Z-direction). In addition, the third transfer gate TG23 of the second sub-pixel group SPX2, the second transfer gate TG32 of the third sub-pixel group SPX3, and the first transfer gate TG41 of the fourth sub-pixel group SPX4 may overlap a portion of the connection wire WR in the third direction (Z-direction).

At this time, the transfer gate wire TWR connected to a transfer gate that does not non-overlap the connection wire WR in the third direction (Z-direction) among transfer gates TG11 to TG14, TG21 to TG24, TG31 to TG34, and TG41 to TG44 may further include the dummy wiring portion DWR protruding from a first side end portion of the transfer gate wire TWR.

For example, as shown in FIG. 12, when the connection wire WR overlap the fourth transfer gate TG14 in the third direction (Z-direction), the transfer gate wire TWR connected to the first to third transfer gate TG11 to TG13 may include the dummy wiring portion DWR. The transfer gate wire TWR connected to the fourth transfer gate TG14 may not include the dummy wiring portion DWR.

The dummy wiring portion DWR may protrude in one direction from the first side end portion of the transfer gate wire TWR. For example, the dummy wiring portion DWR may protrude in the first direction (X-direction) from the first side end portion of the transfer gate wire TWR. Alternatively, the dummy wiring portion DWR may protrude in the second direction (Y-direction) from the first side end portion of the transfer gate wire TWR.

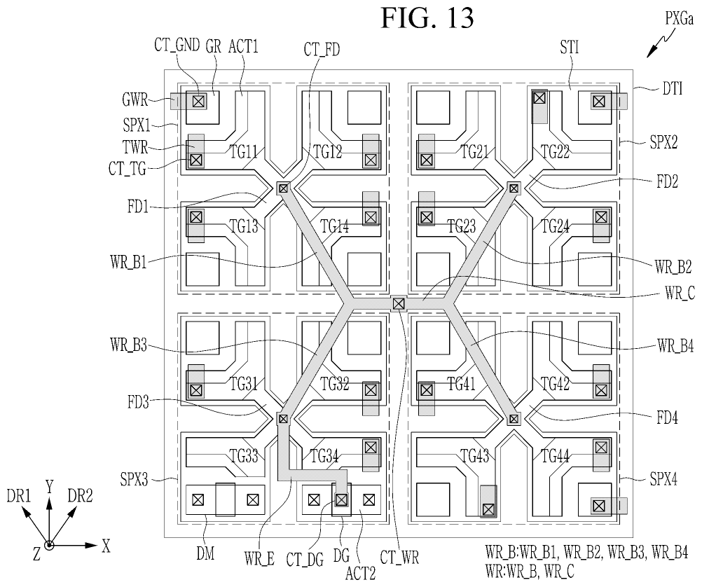

FIG. 13 to FIG. 15 are top plan views schematically showing a pixel group of an image sensor according to some embodiments. An image sensor according to an embodiment shown in FIG. 13 to FIG. 15 has substantially same parts as an image sensor according to an embodiment shown in FIG. 1 to FIG. 8, and thus the following description is more focused on differences while omitting redundant explanations

In addition, same reference numerals are used for same elements as in the previous embodiment. The present embodiment is partially different from the above embodiment in that the pixel group further includes a driving gate, which will be described below.

Referring to FIG. 13 to FIG. 15, in the same way as above embodiment, the pixel group PXGa of the image sensor 100 according to some embodiments may include the first to fourth sub-pixel groups SPX1 to SPX4, and the connection wire WR configured to connect the first to fourth sub-pixel groups SPX1 to SPX4. The connection wire WR may include the central connection portion WR_C located at the central portion of the rectangular shape and the plurality of bridge portions WR_B configured to connect between the central connection portion WR_C and the first to fourth vertices VT1 to VT4 of the rectangular shape.

Referring to FIG. 13 to FIG. 15, the pixel group PXGa of the image sensor 100 according to the present embodiment may further include a driving gate DG. The driving gate DG may be located within a sub-the pixel group PXGa. For example, as shown in FIG. 13, the driving gate DG may be located in a pixel of a third sub-the pixel group PXGa. The driving gate DG may be located above the isolation layer STI. The driving gate DG may be located adjacent to the fourth transfer gate TG34 of the third sub-the pixel group PXGa, but is not limited thereto. The driving gate DG may be gate of the driving transistor (DX of FIG. 3). The driving gate DG may be connected to the connection wire WR through a driving contact CT_DG.

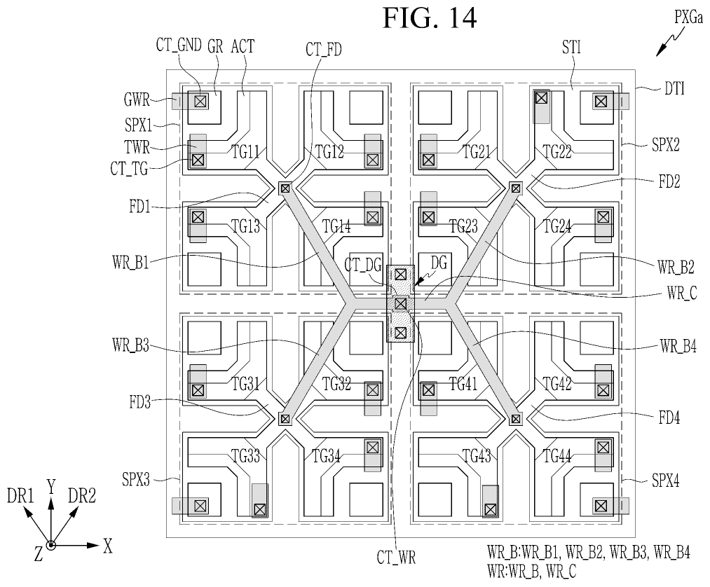

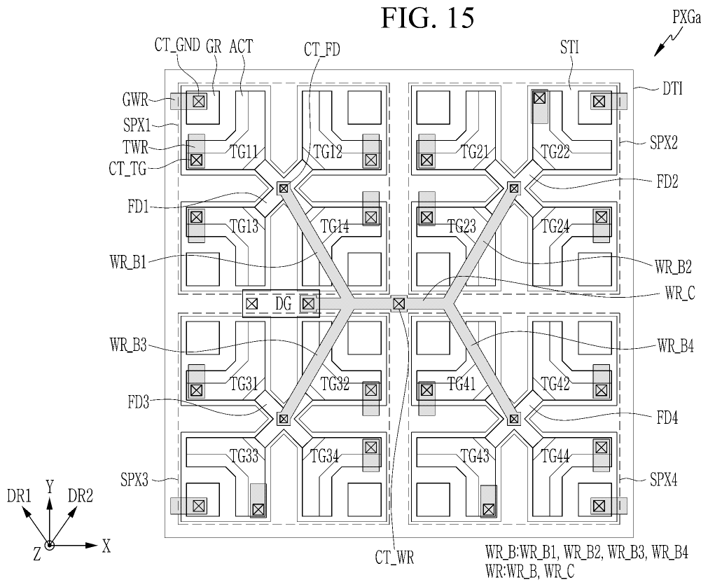

Alternatively, as shown in FIG. 14, the driving gate DG may have a shape extending long along the second direction (Y-direction) from a center of the pixel group PXGa. The driving gate DG may overlap the pixel separator DTI. The driving gate DG may be disposed between the first and third sub-pixel groups SPX1 and SPX3 and the second and fourth sub-pixel groups SPX2 and SPX4. Alternatively, as shown in FIG. 15, the driving gate DG may have a shape extending long along the first direction (X-direction) between the first sub-pixel group SPX1 and the third sub-pixel group SPX3. The driving gate DG may overlap the pixel separator DTI.

Referring back to FIG. 13, in some embodiments, the connection wire WR may further include an extension portion WR_E. The extension portion WR_E may be located between the driving contact CT_DG and one side of one bridge portion (for example, the third bridge portion WR_B3) among the plurality of bridge portions WR_B. However, it is not limited thereto, and the extension portion WR_E may have various shapes to connect the connection wire WR and the driving gate DG. For example, the extension portion WR_E may be connected to the first side end portion of the central connection portion WR_C. The driving gate DG may be connected to the connection wire WR through the extension portion WR_E. In some embodiments, as shown in FIG. 13, the pixel group PXGa may further include a dummy gate DM. The dummy gate DM may be located in a pixel of the sub-the pixel group PXGa. However, it is not limited thereto, and the dummy gate DM may be located above the isolation layer STI.

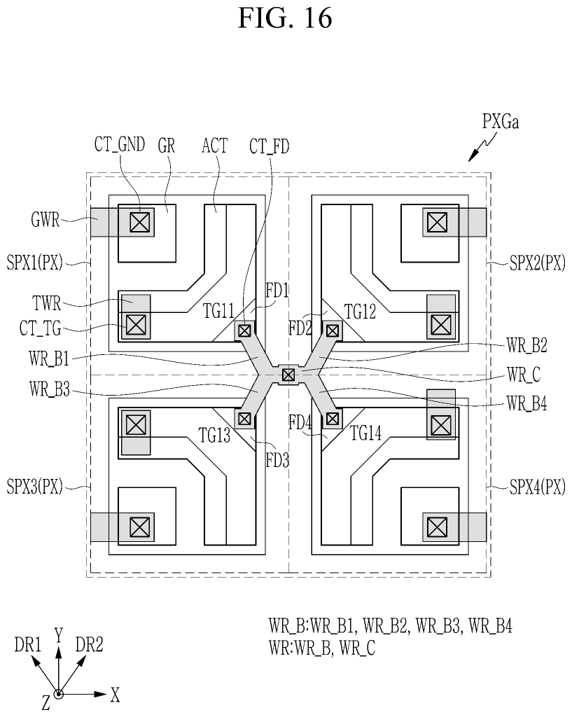

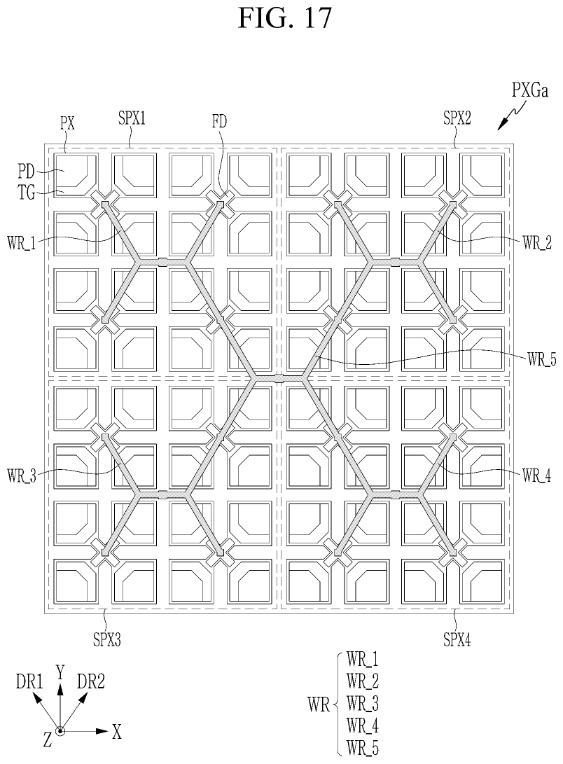

FIG. 16 and FIG. 17 are top plan views schematically showing a pixel group of an image sensor according to some embodiments. An image sensor according to an embodiment shown in FIG. 16 and FIG. 17 has substantially same parts as an image sensor according to an embodiment shown in FIG. 1 to FIG. 8, and thus the following description is more focused on differences while omitting redundant explanations. In addition, same reference numerals are used for same elements as in the previous embodiment. The present embodiment differs from the above embodiments in the number of pixels included in a pixel group, which will be described below.

Referring to FIG. 16 and FIG. 17, in the same way as above embodiment, the pixel group PXGa of the image sensor 100 according to some embodiments may include the first to fourth sub-pixel groups SPX1 to SPX4, and the connection wire WR configured to connect the first to fourth sub-pixel groups SPX1 to SPX4. The connection wire WR may include the central connection portion WR_C located at the central portion of the rectangular shape and the plurality of bridge portions WR_B configured to connect between the central connection portion WR_C and the first to fourth vertices VT1 to VT4 of the rectangular shape.

The first to fourth sub-pixel groups SPX1 to SPX4 of the above embodiment may include the first to fourth pixels PX1 to PX4 arranged along the plurality of columns and the plurality of rows, respectively. That is, first to fourth sub-the pixel group PXGa each may include four photodiodes and four transfer gates. For example, the first sub-pixel group SPX1 may include the first to fourth photodiodes PD11 to PD14, the first to fourth transfer gates TG11 to TG14 and the first floating diffusion region FD1.

Referring to FIG. 16, the first to fourth sub-pixel groups SPX1 to SPX4 each of the image sensor 100 according to the present embodiment may include one pixel PX. Each of the first to fourth sub-pixel groups SPX1 to SPX4 may include one photodiode, one transfer gate, and one floating diffusion region. In more detail, first sub-the pixel group PXGa may include the first transfer gate TG11 and the first floating diffusion region FD1. First sub-the pixel group PXGa may include a corresponding first photodiode for each pixel PX.

Second sub-the pixel group PXGa may include the second transfer gate TG12 and the second floating diffusion region FD2. Second sub-the pixel group PXGa may include a corresponding second photodiode for each pixel PX. The third sub-the pixel group PXGa may include the third transfer gate TG13 and the third floating diffusion region FD3. The third sub-the pixel group PXGa may include a corresponding third photodiode for each pixel PX. Fourth sub-the pixel group PXGa may include the fourth transfer gate TG14 and the fourth floating diffusion region FD4. Fourth sub-the pixel group PXGa may include a corresponding fourth photodiode for each pixel PX. The connection wire WR may be connected to the first to fourth floating diffusion regions FD1 to FD4 through the floating diffusion contact CT_FD.

Alternatively, referring to FIG. 17, the first to fourth sub-pixel groups SPX1 to SPX4 each of the image sensor 100 according to the present embodiment may include 16 pixels PX. Each of the first to fourth sub-pixel groups SPX1 to SPX4 may include 16 photodiodes PD, 16 transfer gates TG, the four floating diffusion regions FD that are arranged along the plurality of columns and the plurality of rows.

First sub-the pixel group PXGa may include a first connection wire WR_1 configured to connect the four floating diffusion regions FD. The first connection wire WR_1 is substantially the same as the connection wire WR of embodiments of FIG. 1 to FIG. 8, and is not redundantly included here again.

Second sub-the pixel group PXGa may include a second connection wire WR_2 configured to connect the four floating diffusion regions FD. The third sub-the pixel group PXGa may include a third connection wire WR_3 configured to connect the four floating diffusion regions FD. Fourth sub-the pixel group PXGa may include a fourth connection wire WR_4 configured to connect the four floating diffusion regions FD. The second to fourth connection wires WR_2 to WR_4 is substantially the same as the connection wire WR of embodiments of FIG. 1 to FIG. 8, and is not redundantly included here again.

Accordingly, each of the first to fourth floating diffusion regions FD1 to FD4 may be connected to at least one photodiode through first to fourth connection wires WR_1 to WR_4. For example, the first floating diffusion region FD1 may be connected to 16 photodiodes PD arranged along the plurality of columns and the plurality of rows through the first connection wire WR_1.

The connection wire WR may further include a fifth connection wire WR configured to connect the first to fourth connection wires WR_1 to WR_4. The shape of the fifth connection wire WR is substantially the same as the connection wire WR of the embodiments of FIG. 1 to FIG. 8, except that the fifth connection wire WR connects between the first to fourth connection wires WR_1 to WR_4 instead of connecting between the first to fourth floating diffusion regions FD1 to FD4, and is not redundantly included here again.

The connection wire WR of the image sensor 100 according to an embodiment may connect between the first to fourth floating diffusion regions FD1 to FD4. Therefore, the first to fourth sub-pixel groups SPX1 to SPX4 may share the first to fourth floating diffusion regions FD1 to FD4. In addition, the first to fourth sub-pixel groups SPX1 to SPX4 may share the output circuit. Accordingly, an available area of the pixel group PXGa may be increased. Since the first to fourth floating diffusion regions FD1 to FD4 are shared within the pixel group PXGa, the sensing sensitivity of the pixel group PXGa may be increased. Accordingly, resolution and sensing sensitivity of the pixel array 140 may be increased.

In this case, parasitic capacitance between the connection wire WR and peripheral elements may decrease as the length of the connection wire WR decreases. The connection wire WR of the image sensor 100 according to an embodiment includes the central connection portion WR_C and the plurality of bridge portions WR_B, a predetermined angle is formed between the central connection portion WR_C and the plurality of bridge portions WR_B and between two bridge portions connected to the first side end portion of the central connection portion WR_C, and thereby the length of the connection wire WR may be reduced. Therefore, parasitic capacitance between the connection wire WR and peripheral elements may be reduced, and optical characteristics of the image sensor 100 may be improved.

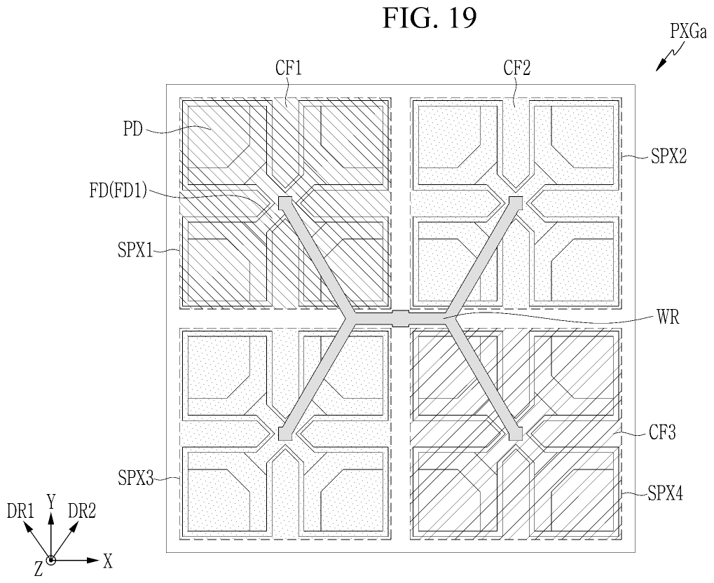

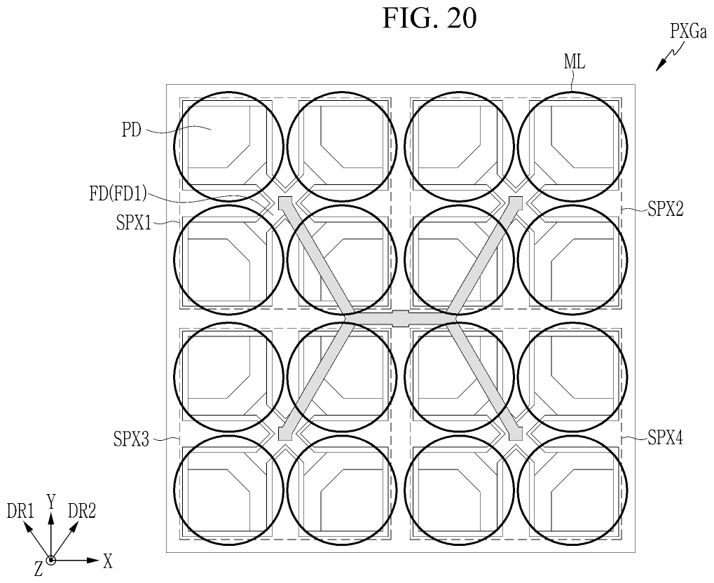

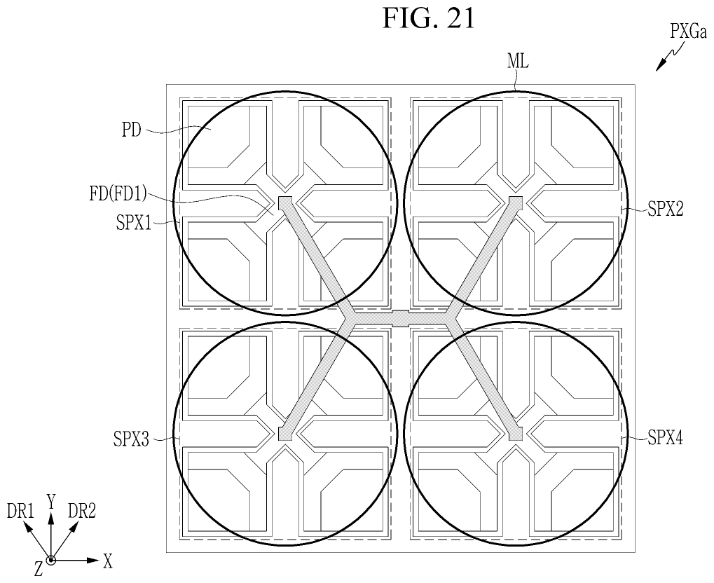

Hereinafter, a color filter and a microlens of an image sensor according to an embodiment will be described with reference to FIG. 18 to FIG. 21. FIG. 18 and FIG. 19 are top plan views schematically showing a color filter of an image sensor according to an embodiment. FIG. 20 and FIG. 21 are top plan views schematically showing a microlens of an image sensor according to an embodiment.

Referring to FIG. 18, as described above, the color filters CF may be located corresponding to each of the photodiodes PD. The color filters CF may include a first color filter CF1, a second color filter CF2, and a third color filter CF3. For example, the first color filter CF1 may be a red color filter, the second color filter CF2 may be a green color filter, and the third color filter CF3 may be a blue color filter.

In an embodiment, the color filters CF may have a Bayer pattern in a plan view. For example, the color filters CFs may have a pattern in which the number of the second color filters CF2 is about twice as many as the number of the first color filters CF1 or the third color filters CF3. That is, in the color filters CF arranged in a 2×2 shape in a plan view, the Bayer pattern may include two second color filters CF2 disposed diagonally to each other, and the first color filter CF1 and the third color filter CF3 disposed diagonally to each other. Each of the first color filter CF1 and the third color filter CF3 may be disposed between adjacent second color filters CF2. The color filters CF of the Bayer pattern may be repeatedly arranged along the first direction (X direction) and the second direction (Y direction).

However, the present disclosure is not limited thereto, and the number of the photodiodes PD corresponding to one color filter CF may be variously changed. For example, N×M photodiodes PDs may correspond to one color filter CF. Here, N and M may each independently be an integer greater than 1. For example, as shown in FIG. 19, when each of N and M is 2, four photodiodes PDs may correspond to one color filter CF.

Referring to FIG. 20, microlenses ML condensing light incident from the outside may be located on each of the photodiodes PD. The microlenses ML may be arranged to correspond to the photo diodes PD. That is, one microlens ML may be disposed on one photo diode PD. That is, the ratio between the number of photodiodes PD and the number of microlenses ML may be 1:1.

However, it is not limited thereto, and the number of diodes PD corresponding to one microlens ML may be variously modified. For example, N×M photodiodes PDs may correspond to one microlens ML. Here, N and M may be independently an integer greater than 1, respectively. For example, as shown in FIG. 21, when each of N and M is 2, four photodiodes PDs may correspond to one microlens ML.

In an embodiment, an upper surface of the microlens ML may have a curved surface. However, the present disclosure is not limited thereto, and in some embodiments, the upper surface of the microlens ML may have the quadrangular shape having rounded corners.

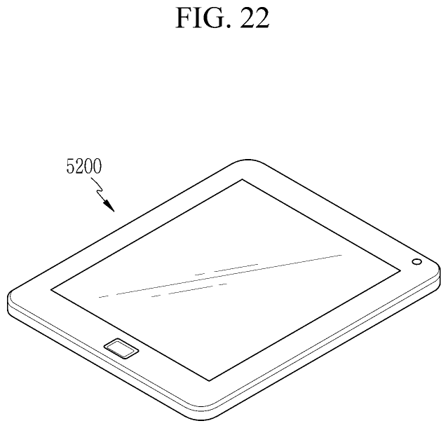

Hereinafter, an application example of the image sensor according to the embodiment will be described with reference to FIG. 22 to FIG. 24. FIG. 22 to FIG. 24 are drawings illustrating various examples of electronic devices to which image sensors according to example embodiments are applied.

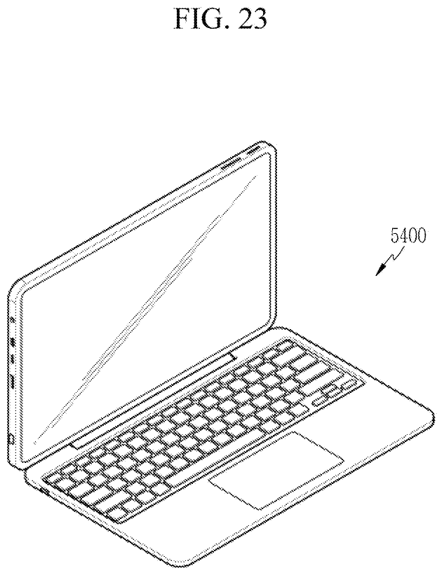

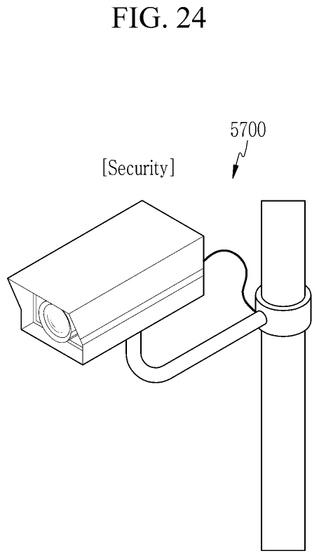

The image sensor 100 according to the embodiments may be applied to a mobile phone or a smart phone, a tablet or a smart tablet 5200 shown in FIG. 22, a laptop computer 5400 shown in FIG. 23, or a security camera 5700 shown in FIG. 24. For example, the smart phone or the smart tablet 5200 may include a plurality of high resolution cameras each equipped with a high resolution image sensor. The high resolution camera may be used to extract depth information from subjects in an image, control out-focusing of the image, or automatically identify subjects in the image. The security camera 5700 may provide ultra-high resolution images and may recognize objects or people in the images even in a dark environment by using high sensitivity.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

1. An image sensor, comprising:
a substrate having a plurality of photodiodes therein;
a plurality of transmission transistors having respective current carrying terminals electrically coupled to corresponding ones of the plurality of photodiodes;
a plurality of floating diffusion regions electrically coupled to current carrying terminals of corresponding ones of the plurality of transmission transistors; and
a connection wire configured to electrically interconnect at least four of the plurality of floating diffusion regions together, said connection wire including:
a central connection segment having first and second ends;
a first connection segment having a first end electrically connected to the first end of the central connection segment and a second end electrically connected to a first of the plurality of floating diffusion regions; and
a second connection segment having a first end electrically connected to the second end of the central connection segment and a second end electrically connected to a second of the plurality of floating diffusion regions;
wherein the first and central connection segments are linear segments, and wherein the first end of the first connection segment intersects with the first end of the central connection segment at an obtuse angle when viewed from a plan layout perspective.

2. (canceled)

3. The image sensor of claim 1, wherein the four of the plurality of floating diffusion regions are located at respective vertices of a rectangle when viewed from a plan layout perspective.

4. The image sensor of claim 3, wherein a distance between the first of the plurality of floating diffusion regions and the first end of the central connection segment is equivalent to a distance between the second of the plurality of floating diffusion regions and the second end of the central connection segment.

5. The image sensor of claim 1, wherein the connection wire further includes:
a third connection segment having a first end electrically connected to the first end of the central connection segment and a second end electrically connected to a third of the plurality of floating diffusion regions; and
a fourth connection segment having a first end electrically connected to the second end of the central connection segment and a second end electrically connected to a fourth of the plurality of floating diffusion regions.

6. The image sensor of claim 5,
wherein the first end of the first connection segment intersects with the first end of the central connection segment at a first obtuse angle when viewed from a plan layout perspective;
wherein the first end of the third connection segment intersects with the first end of the central connection segment at a third obtuse angle when viewed from a plan layout perspective;
wherein the first end of the second connection segment intersects with the second end of the central connection segment at a second obtuse angle when viewed from a plan layout perspective; and
wherein the first end of the fourth connection segment intersects with the second end of the central connection segment at a fourth obtuse angle when viewed from a plan layout perspective.

7. The image sensor of claim 6, wherein the first and third obtuse angles are equivalent; and wherein the second and fourth obtuse angles are equivalent.

8.-10. (canceled)

11. An image sensor, comprising:
a substrate;
a plurality of photodiodes located in the substrate;
transmission transistors connected to the plurality of photodiodes, respectively;
a plurality of floating diffusion regions connected to at least one photodiode through the transmission transistors; and
a connection wire configured to interconnect at least four floating diffusion regions,
wherein the four floating diffusion regions are located on vertices of a rectangular shape, respectively,
wherein the connection wire comprises a central connection portion located in a central portion of the rectangular shape, and a plurality of bridge portions configured to connect between the central connection portion and each vertex of the rectangular shape,
wherein a first angle between two bridge portions connected to a first side end portion of the central connection portion among the plurality of bridge portions is an obtuse angle, and
wherein an angle between the bridge portion and a short side of the rectangular shape is smaller than an angle between the short side and a diagonal line of the rectangular shape.

12. The image sensor of claim 11, wherein the central connection portion extends parallel to a long side of the rectangular shape.

13. The image sensor of claim 12, wherein two bridge portions connected to the first side end portion of the central connection portion among the plurality of bridge portions are symmetrical with respect to the central connection portion.

14. The image sensor of claim 12, wherein angles between the central connection portion and respective ones in the plurality of bridge portions are the same.

15. The image sensor of claim 11, wherein the first angle is greater than or equal to 110 degrees, and smaller than or equal to 130 degrees.

16. The image sensor of claim 15, wherein the first angle is 120 degrees, and angles between the central connection portion and respective ones in the plurality of bridge portions are 120 degrees.

17. The image sensor of claim 11, wherein each of the plurality of floating diffusion regions is connected to four photodiodes arranged in a plurality of rows and a plurality of columns.

18. An image sensor, comprising:
a substrate;
a plurality of photodiodes located in the substrate;
transmission transistors connected to the plurality of photodiodes, respectively;
a plurality of floating diffusion regions connected to at least two photodiodes through the transmission transistors; and
a connection wire configured to interconnect at least four floating diffusion regions,
wherein the four floating diffusion regions are located at vertices of a quadrangular shape, respectively, and
wherein a length of the connection wire is smaller than a sum of lengths of two diagonal lines of the quadrangular shape.

19. The image sensor of claim 18, wherein:
the quadrangular shape is a rectangular shape; and
the length of the connection wire is smaller than a sum of twice a length of the short side of the rectangular shape and a length of a long side of the rectangular shape.

20. The image sensor of claim 19, wherein the connection wire comprises:
a central connection portion located in a central portion of the rectangular shape; and
a plurality of bridge portions configured to connect between the central connection portion and respective vertices of the rectangular shape,
wherein a first angle between two bridge portions connected to a first side end portion of the central connection portion among the plurality of bridge portions is greater than 110 degrees, and smaller than or equal to 130 degrees.

21. The image sensor of claim 20, wherein the first angle is 120 degrees, and angles between the central connection portion and respective ones in the plurality of bridge portions are 120 degrees.

22. The image sensor of claim 18, further comprising a transfer gate wire electrically connected to transfer gates of the transmission transistors,
wherein the connection wire non-overlaps the transfer gate wire in a thickness direction of the substrate.

23. The image sensor of claim 22, wherein a transfer gate of at least one transmission transistor among the transmission transistors overlaps at least a portion of the connection wire in the thickness direction of the substrate.

24. The image sensor of claim 23, wherein a transfer gate wire connected to a transfer gate of a transmission transistor non-overlapping the connection wire in the thickness direction of the substrate, among the transmission transistors, further comprises a dummy wiring portion protruding from a first side of the transfer gate wire.

25.-32. (canceled)
